(19) United States
(12) Patent Application Publication
(10) Pub. No.: US 2015/0380168 A1
(43) Pub. Date: Dec. 31, 2015

(54) THIN-LAYER CAPACITORS WITH LARGE SCALE INTEGRATION

(71) Applicant: SIEMENS AKTIENGESELLSCHAFT, München (DE)

(72) Inventors: Maria ARKHIPOVA, Neu-Ulm (DE); David HARTMANN, Erlangen (DE); Andreas KANITZ, Hoechstadt (DE); Willi KANTLEHNER, Aalen (DE); Gerhard MAAS, Senden (DE); Guenter SCHMID, Hemhofen (DE); Dan TAROATA, Erlangen (DE)

(73) Assignee: SIEMENS AKTIENGESELLSCHAFT, Munich (DE)

(21) Appl. No.: 14/767,483

(22) PCT Filed: Jan. 27, 2014
(86) PCT No.: PCT/EP2014/051478

§ 371 Date: Aug. 12, 2015

(30) Foreign Application Priority Data
Feb. 12, 2013 (DE) 10 2013 202 252.2

(51) Int. Cl. H01G 9/07; H01G 9/04; H05K 1/18; H01G 9/00

(52) U.S. Cl. CPC H01G 9/07; H01G 9/0032; H01G 9/0036; H01G 9/04; H05K 1/181; H05K 2201/10015

(57) ABSTRACT

A two-ply, dielectric layer for a thin-layer capacitor, has a bottom, first ply formed of a self-assembled monolayer containing phosphorus oxo compounds and has a top, second ply serving as a planarization layer, the second ply containing guanidinium compounds.

### CROSS REFERENCE TO RELATED APPLICATIONS

This application is based on and hereby claims priority to International Application No. PCT/EP2014/051478 filed on Jan. 27, 2014 and German Application No. 10 2013 202 252.2 filed on Feb. 12, 2013, the contents of which are hereby incorporated by reference.

### BACKGROUND

The present invention relates to a two-layer, dielectric layer for a thin-film capacitor, characterized in that a) the lower first layer comprises a self-assembled monolayer containing phosphoroxo compounds and b) the upper second layer comprises a planarization layer containing guanidinium compounds.

Circuit boards nowadays serve not only for simple wiring and mechanical fastening of electronic components. Owing to the need, for cost and space reasons, to provide circuits having ever higher integration densities, “3D packaging” is carried out in modern designs, with, in particular, passive components such as resistances and capacitors being integrated into the circuit board. This also takes account of the fact that ever wider data buses are used for reliable communication between the components (signal-noise ratio) with increasing cycle frequency in commodity products such as computer main boards or mobile telephone circuit boards, and these require an increasing number of capacitive sinks. While the ratio of capacitors to resistances was previously at a ratio of 1:1, it has now risen to a ratio of 3:1 due to the changed requirements. In addition, “3D packaging” offers, particularly for boards with integrated capacitors, a higher capacity in constant-voltage or low-frequency applications, with the integrated capacitors being used as auxiliary capacitors or for voltage smoothing.

The integration of capacitors in particular can accordingly be advantageous, since:

thousands of capacitors can be produced simultaneously by parallel processing,

the integrated capacitor is very robust and reliable,

both standard circuit boards and also a prepreg can be used,

the construction height of the capacitor is negligibly small compared to the roughness of the substrate material and

a very high integration density (capacitance/area) can be achieved.

In particular, it has been found that a two-layer construction of thin-film capacitors having a self-assembled monolayer and a planarization layer can lead to higher capacitor capacitances. Thus, for example, DE 1020 09037691 A1 describes a possible industrial configuration for thin-film capacitors, which contains a protective layer for a self-assembled monolayer comprising oxidic nanoparticles having a high dielectric constant. The oxidic nanoparticles have an average particle size of less than 50 nm and have a protective shell which stabilizes them against agglomeration and aggregation. Furthermore, components which are based on organic electronics and are integrated into a circuit board, a prepreg or a plate are disclosed, with the plate, circuit board or the prepreg serving as substrate.

A further possibility is described in DE 1020 10063718 A1, in which a dielectric layer for an electrical component having an organic dielectric on a circuit board substrate is disclosed and the dielectric layer comprises an ionic liquid. This construction makes it possible to provide electrical components such as capacitive components which are arranged on a circuit board substrate, a prepreg or a circuit board.

### SUMMARY

It is therefore an object of the present invention to provide a particular class of compounds for the formation of a planarization layer of a two-layer thin-film capacitor, which contributes to improved capacity, an increased life and a cheaper production of the capacitors.

The inventors have now surprisingly found that two-layer thin-film capacitors having a planarization layer which contains a guanidinium compound have significantly improved properties compared to the related art. The guanidinium compounds belong generally to the class of ionic liquids (IL). These liquids are particularly suitable for formation of the planarization layer. The guanidinium compounds in particular have improved properties compared to the other members of the IL class.

The proposed use of the class of guanidinium compounds as planarization layer has been arrived at by testing of a specific requirement specification which leads to compounds which are particularly suitable for use in thin-film capacitors. In selecting the compounds for the planarization layer in the production of two-layer thin-film capacitors, particular attention has been paid to:

a) The Phase Behavior

The compounds should be liquid in the use temperature range and have a very low viscosity at the operating temperature. This allows higher mobility of the charge carriers and thus leads to a quicker response. Furthermore, a broader processing window is obtained. A proven way of adapting the phase behavior of the IL is generally effected via selection of the substituents of the guanidinium compound. Thus, for example, the bonding of bulky organic side groups to the cation generally leads to a lower IL melting point.

b) The Residual Moisture Content

The guanidinium compound should, as compound, not be hygroscopic. Furthermore, the residual moisture content of the guanidinium compounds should be kept very low during processing and should be vanishing for the best results. This can be ensured, for example, by predrying of the guanidinium compound or by use of a protective gas during processing. A low residual moisture content prevents corrosion of water-sensitive metals and enlarges the electrochemical window of the compound. In particular, the decomposition of water on the integrated components by high applied voltages can lead to damage to the material by evolution of oxygen and hydrogen.

c) The Electrochemical Stability

The guanidinium compound should have a high electrochemical stability and, associated therewith, a wide electrochemical window. This reduces the opportunities for undesirable secondary reactions in the component and decomposition of the planarization layer. A smaller amount of undesirable by-products accumulates, which increases the life of the thin-film capacitor.

d) The Chemical Stability

The guanidinium compound should be chemically inert. Apart from the loss of the electrolyte by electrochemical processes, the loss of the guanidinium compound by reactions with the other constituents of the thin-film capacitor should also be ruled out. This avoids an excessively short life and capacitance losses of the thin-film capacitor.

Taking into account the abovementioned points, there is accordingly a defined class of compounds which is particularly suitable as planarization layer for the production of thin-film capacitors. The guanidinium compounds in particular display an extraordinary electrochemical stability (Trans. Nonferrous Met. Soc. China 19 (2009)).

The inventors propose a two-layer, dielectric layer for a thin-film capacitor, characterized in that a) the lower first layer comprises a self-assembled monolayer containing phosphoroxo compounds and b) the upper second layer comprises a planarization layer containing guanidinium compounds.

As a result of the proposed of the two-layer dielectric layer having a lower, self-assembled monolayer (SAM) containing phosphoroxo compounds and an upper planarization layer containing a guanidinium compound, a higher capacity of the thin-film capacitor compared to the prior art is achieved. Selection of the material of the planarization layer in particular gives very stable and long-life capacitors which achieve integration densities up to more than 1 μF/mm². This is significantly higher than is described in the related art. Without wishing to be tied to a theory, the long life of the thin-film capacitor results particularly from the chemical and electrochemical stability of the guanidinium compounds used and from the good leakage current behavior of the SAM. The substance class of guanidinium compounds in particular leads, in combination with a phosphoroxo SAM, to very advantageous dielectric behavior with a very high dielectric constant of the total layer, which is the cause of both the high capacitance of the thin-layer capacitor and also the longevity thereof. This is astonishing since guanidinium compounds can also have a partial electrical conductivity.

The term self-assembled monolayer (SAM) refers to a layer formed of only one molecular layer which adheres by an anchor group to a substrate. As a result of the interactions with the substrate and the intermolecular interactions, the individual molecules in the layer become aligned and form an ordered dielectric layer, possibly also with approximately parallel alignment of the individual molecules. The choice of the compounds of the monolayer determines mainly the leakage current behavior and the reliability of the thin-film capacitor. The phosphoroxo compounds in particular display extraordinarily good alignment on the conventional substrates of circuit board manufacture, e.g. copper.

Phosphoroxo compounds are, for the purposes of the proposals, organic phosphoric acid or phosphonic acid derivatives having at least one organic radical which in the case of the phosphoric acid compounds is bound via the oxygen and in the case of the phosphonic acid compounds via the phosphorus and is selected from the group consisting of linear, branched or cyclic C5-C25 alkyl, aryl, heteroalkyl, heteroaryl.

According to the proposals, the planarization layer comprises a guanidinium compound and is arranged on the SAM. The planarization layer fulfills two functions here. Firstly, the planarization layer improves the dielectric properties of the thin-film capacitor, and secondly the second layer leads to a reduction in the surface roughness of the substrate. For this reason, less surface-rough structures on which a further metal electrode can be deposited more easily are obtained as a result of this construction. The surface roughness is determined substantially by the roughness of the substrate.

The guanidinium compounds in the planarization layer can contain guanidinium cations and the anions required for charge neutrality. The guanidinium cations can correspond to the general formula (I) below

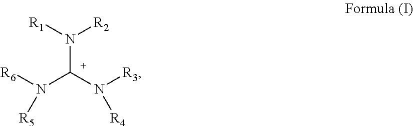

where the substituents R₁-R₆ can be selected from the group consisting of linear, branched or cyclic C1-C25 alkyl, aryl, heteroalkyl, heteroaryl, oligoethers (e.g. [—CH₂—CH₂—O—]ₙ, oligoesters (e.g. [—CH₂—CO—O—]ₙ, oligoamides, oligoacrylamides and hydrogen. Furthermore, a plurality of the substituents can also be bridged with one another via cyclic or heterocyclic compounds. It is possible to use only one guanidinium compound or a mixture of guanidinium compounds in the planarization layer.

In a particular embodiment, at least one of the substitution patterns of a nitrogen of the guanidinium compound can be different from the two other substitution patterns of the guanidinium nitrogens, i.e. an asymmetrically substituted guanidinium compound is obtained. This can result in advantages in the processing of the guanidinium compound.

In a particular embodiment, the two-layer, dielectric layer can contain guanidinium compounds selected from the group consisting of guanidinium salts, bisguanidinium salts and guanidinium betaines. The charged guanidinium compounds in particular, which additionally have the structures, can contribute both to an increase in the dielectric constant of the two-layer dielectric layer and to very good processability. This makes it possible to obtain particularly high capacitances for thin-film capacitors. This class of compounds has in common the positive charge of the guanidinium compound, which is delocalized over the guanidinium nitrogens. In particular, a specific embodiment of the class of compounds displays a low intrinsic conductivity and a large electrochemical window.

The general structures of the bisguanidinium salts are given by the general formula (II)

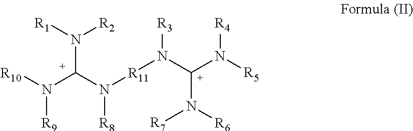

and for the guanidinium betaines by the formula (III)

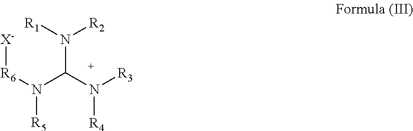

The substituents R₁-R₁₁ can be selected independently from the group consisting of linear, branched or cyclic C1-C25 alkyl, aryl, heteroalkyl, heteroaryl, oligoethers (e.g. [—CH₂—CH₂—O—]ₙ, oligoesters (e.g. [—CH₂—CO—O—]ₙ), oligoamides, oligoacrylamides and hydrogen. For the substituents R₁₁, the abovementioned group without the hydrogen applies. Furthermore, a plurality of the substituents can also be bridged with one another via cyclic or heterocyclic compounds.

The substituent X can be selected from the group consisting of halogen, —OH, —CN, —COOH.

In a particular embodiment, at least one of the substitution patterns of a nitrogen of the bisguanidinium cation is different from the two other guanidinium nitrogen substitution patterns, i.e. an asymmetrical bisguanidinium compound is obtained. The asymmetry can result in a particularly low melting point of the compounds and thus advantages in the processing of the guanidinium compounds.

In a further aspect, the planarization layer of the two-layer, dielectric layer can comprise a guanidinium salt whose cation corresponds to the formula (IV) below:

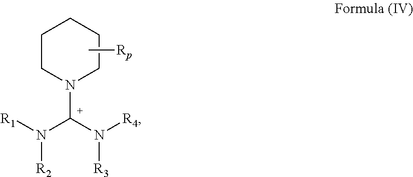

where Rₚ=branched, unbranched or cyclic C1-C20 alkyl, heteroalkyl, aromatics, heteroaromatics and R₁-R₄ can be selected independently from the group consisting of branched or unbranched C1-C20 alkyl, heteroalkyl, oligoethers, oligoesters, oligoamides, oligoacrylamides. Especially the use of a guanidinium compound having a guanidinium cation in which one of the nitrogens is integrated within a 6-membered heterocycle displays particular chemical and electrochemical stability and a significant improvement in the dielectric constant of the two-layer dielectric layer. This can lead to particularly high-performance thin-film capacitors. The further substituents R₁-R₄ can influence the solubility and the melting point of the guanidinium compound and thus lead to better processability of the compound. For the purposes, oligoethers are, for example, substituents having the following structure [—CH₂—CH₂—O—]ₙ, where n is an integer and can be selected in the range from 1 to 10. Oligoesters as substituents have one or more structural units of the formula [—CH₂—CO—O—]ₙ, where n is an integer and can be selected in the range from 1 to 10. The structures of the oligoamide substituents are analogously [—CO—NR—]ₙ and the structures of the oligoacrylamide substituents are analogously [—CH₂—CHCONH₂—]ₙ.

In a particular embodiment, at least two of the substituents R₁-R₄ in the formula (IV) can be selected from the group consisting of C10-C20 alkyl, heteroalkyl, oligoethers, oligoesters, oligoamides, oligoacrylamides. These relatively long-chain substituents can contribute to particularly good stability of the planarization layer and to a high dielectric constant. The relatively long-chain variants also have good solubility, so that they can be processed more easily to give solution-processable, in particular printable, formulations.

In a particular embodiment, Rₚ can also be present as substituent on the base skeleton. The substituents Rₚ can be selected from the group consisting of furan, thiophene, pyrrole, oxazole, thiazole, imidazole, isoxazole, isothiazole, pyrazole, pyridine, pyrazine, pyrimidine, 1,3,6-triazine, pyrylium, alpha-pyrones, gamma-pyrones, benzofuran, benzothiophene, indole, 2H-isoindole, benzothiazole, 2-benzothiophenes, 1H-benzimidazoles, 1H-benzotriazoles, 1,3-benzoxazoles, 2-benzofuran, 7H-purines, quinoline, isoquinoline, quinazolines, quinoxalines, phthalazines, 1,2,4-benzotriazines, pyrido[2,3-d]pyrimidines, pyrido[3,2-d]pyrimidines, pteridines, acridines, phenazines, benzo[g]pteridines, 9H-carbazoles and bipyridine and derivatives thereof. The bonding of Rp to the piperidine ring can be effected at any bonding-capable position on the piperidine ring.

In an additional embodiment of the two-layer, dielectric layer, the guanidinium compounds of the planarization layer can contain anions selected from the group consisting of fluorophosphates, fluoroborates, phenylborates, sulfonimides, trifluoromethanesulfonates, bis(trifluoromethylsulfonyl)imides, sulfonates, sulfates, chlorides, bromides and/or benzoates. Apart from the steric configuration of the basic guanidinium skeleton, the melting point and thus the processability of the guanidinium compound can be influenced to a high degree by the choice of the anion of the guanidinium compounds. The abovementioned anions lead to very chemically and electrochemically stable guanidinium compounds having low melting points and a wide electrochemical window.

In a further, preferred embodiment of the process, the guanidinium compound contains anions selected from the group consisting of hexafluorophosphate (PF₆⁻), tetrafluoroborate (BF₄⁻) and bistrifluoromethylsulfonamide (tf₂N⁻).

In a further aspect, the two-layer, dielectric layer can have a planarization layer having a thickness of less than or equal to 10 000 nm. The thickness of the planarization layer can in principle be selected at will and should be guided by the roughness of the substrate. To ensure compatibility in the circuit board processes, the layer thickness of the planarization layer is less than 10 000 nm, preferably less than 1000 nm, particularly preferably less than 500 nm. The lower layer thickness limit can advantageously be greater than or equal to 10 nm, preferably greater than or equal to 50 nm and particularly preferably greater than or equal to 100 nm.

Furthermore, in a further embodiment, the two-layer, dielectric layer can comprise phosphoroxo compounds, with the phosphoroxo compounds of the self-assembled monolayer being selected from the group consisting of organic phosphonic acids, organic phosphonic esters and phosphonic acid amides. The phosphonic acid and/or phosphonic ester anchor group has been found to be most suitable for a variety of support materials, in particular for copper. This anchor group can be deposited directly on the support material, with the phosphonic esters being hydrolyzed during deposition and binding as phosphonate to the surface. In particular, the surface thus does not have to be additionally functionalized with aluminum or titanium by additional deposition (as described, for example, in DE10 2004 005082 B4 for silane anchor groups). Such a functionalization for the surface can be completely dispensed with in the case of the dielectric layer.

For the purposes, phosphonic acid compounds are substances having a structure corresponding to formula (V) below

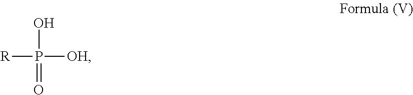

where R is an organic radical. The organic radical R can be selected from the group consisting of linear, branched or cyclic C5-C30 alkyl, aryl, heteroalkyl, heteroaryl. Furthermore, the phosphonic acid compounds can be either uncharged or present as anions during the deposition of the SAM. Transformation of the uncharged phosphonic acid derivatives into the corresponding anions can be effected by addition of the appropriate bases during the dissolution and deposition process. The alkyl chain can also contain a head group selected from among aromatics and heteroaromatics, e.g. phenyl or phenoxy. The pi-pi interaction of this head group can reinforce the stability of the self-assembled monolayer.

In a further embodiment, the two-layer dielectric layer can have an SAM which comprises phosphonic acid compounds and in which the phosphonic acid compounds of the self-assembled monolayer correspond to the general formula (VI)

CH₃—(CH₂)ₙ—PO(OH)₂ Formula (VI),

where n is greater than or equal to 2 and less than or equal to 25. Furthermore, n can preferably be greater than or equal to 8 and less than or equal to 25 and particularly preferably be greater than or equal to 14 and less than or equal to 20. These relatively long-chain phosphonic acid compounds can contribute to formation of particularly low-leakage-current layers. In a particular embodiment, n can be 18 or 14.

Furthermore, the molecular chain for formation of the SAM can also be configured as a polyether chain (—O—CH₂—CH₂—O—)ₘ, where m is in the range from 1 to 20, preferably from 2 to 10. The alkyl chains of the phosphonic acid compounds can also be fully or partially fluorinated. As an alternative, the deposition can also be effected via phosphonic esters or salts thereof or other derivatives such as amides, etc. The salts can be obtained directly in solution by addition of relatively small or equivalent amounts of alkali (NaOH, KOH, ammonia or ammonium hydroxides).

In a preferred embodiment, the two-layer, dielectric layer can contain a planarization layer which additionally comprises polymeric substances. In particular cases, a particularly high mechanical stability or chemical inertness of the planarization layer can be desired. This is, for example, in the case in which the surface of the support is particularly rough and a particularly thick planarization layer is applied. Furthermore, the layer thickness of the planarization layer can also be utilized as a parameter for fixing the capacitor capacitance or integration density. In these cases, further polymeric substances can be mixed in addition to the guanidinium compounds into the planarization layer. These can increase the viscosity of the guanidinium compound and lead to a greater mechanical strength of the planarization layer. To obtain a strong dielectric layer, it is possible to use a mass ratio of polymer:guanidinium compound of, for example, from 1:1000 to 1000:1. If the melting point of the guanidinium compound is sufficiently high, this can also be used in pure form.

In a further preferred embodiment, the two-layer, dielectric layer can comprise polymeric substances selected from the group consisting of epoxides, polyacrylates, polyurethanes, polycarbonates, polyesters, polyamides, polyimides, polybenzoxazoles, polyvinylidene difluorides, polyvinyl compounds, polycarbazoles and phenol/formaldehyde compounds. The abovementioned polymeric compounds display, on the one hand, a sufficient viscosity together with the guanidinium compounds to form a mechanically extremely strong planarization layer and on the other hand are sufficiently chemically and electrochemically inert to display no secondary reaction with the other layers of the thin-film capacitor. Furthermore, the polymeric compounds are substances which form non-Newtonian liquids. This can simplify processing from a solution and contribute to formation of a very uniform planarization layer. It is also possible to use mixtures of the abovementioned polymeric compounds. The molar mass of the polymers can be in the range from 1000 to 1 000 000 g/mol. Furthermore, it is also possible to use copolymers or block copolymers such as acrylonitrile-butadiene-stryene copolymer (ABS), styrene-acrylonitrile (SAN), polyethylene oxide-b-polypropylene oxide (PEO-b-PPO), Pluronic, Brij and/or poloxamines as polymeric additives to form the planarization layer.

The inventors also propose a process for producing a thin-film capacitor having a two-layer, dielectric layer, which comprises:

i) provision of a substrate support having a first electrode,
ii) application of a self-assembled monolayer containing organic phosphorus oxo compounds,
iii) application of a planarization layer containing guanidinium compounds and
iv) application of a second metallic layer.

A copper plate which has been pickled by conventional methods and has an applied layer of about 1-30 μm of copper or a prepreg can serve as base material for the thin-film capacitor). The pickling of a copper plate can be carried out as usual by degreasing of the copper plate by organic solvents and subsequent partial corrosion using peroxodisulfates and sulfuric acid. The monolayer containing phosphoroxo compounds can be deposited on this pretreated surface in a subsequent process (ii). This is preferably effected by a wet-chemical or solvent process. This operation can be monitored analytically by measuring the contact angle relative to water. The contact angle relative to water can increase to >130° after deposition of, for example, an alkylphosphonic acid. The SAM can, for example, be dried by a thermal process in a subsequent operation.

The application of the planarization layer (iii) can likewise be effected by a wet-chemical or solvent process. As a function of the melting point of the guanidinium compound, the guanidinium compound can be used alone or as a solution in a solvent. Furthermore, polymeric substances can be added at this point. As suitable organic solvents, it is possible to use, for example, propylene glycol monoethyl ether acetate (PGMEA), tetrahydrofuran, dioxane, chlorobenzene, diethylene glycol diethyl ether, diethylene glycol monoethyl ether, gamma-butyrolactone, N-methylpyrrolidone, ethoxyethanol, xylene, toluene or similar solvents. The planarization layer can then be dried by, for example, a thermal process in a subsequent operation in a manner analogous to (ii) above.

In a particular embodiment, the substances used in the solvent processes are water-free, i.e. they substantially have a water content of <0.1% by weight. The water content can be determined by the conventional methods of the related art. Mention may at this point be made of water determination by the Karl-Fischer method.

As covering electrodes for the thin-film capacitor (iv), it is possible to use any metal or alloy thereof or conductive metal-containing printing pastes. The covering electrode can also be formed of conductive oxides such as tin-doped indium oxide or aluminum-doped zinc oxide. Organic conductors such as PEDOT (polystyrenesulfonic acid-doped polydiethoxythiophene) or PANI (camphorsulfonic acid-doped polyaniline) are likewise suitable. However, particular preference is given to the metals copper, aluminum, nickel, gold and silver and alloys thereof utilized in the circuit board industry. Metal counterelectrodes applied over the full area can subsequently be structured by the etching and mechanical ablation processes (laser) known to those skilled in the art. If a plurality of thin-film capacitors are provided with a common counterelectrode, the deposition of the counterelectrode can also be effected from the gas phase by shadow masks. The counterelectrodes can also be applied by electroless metallization after local or full-area seeding. In principle, all processes of the circuit board industry can be used in this.

In a further aspect of the process for producing a thin-film capacitor, the application of the self-assembled monolayer and/or the application of the planarization layer can be effected by spin coating, slot coating, printing, centrifugation, dipping, curtain coating or doctor blade coating. These processes are particularly suitable for forming a uniform and hole-free layer in the indicated thickness range of the SAM and the planarization layer. Due to the shear forces which occur, the non-Newtonian solutions or pure guanidinium compound can effectively get into the rough surfaces of the circuit boards and thus form an effective dielectric surface layer.

In an alternative embodiment of the process for producing a thin-film capacitor having a two-layer, dielectric layer, the planarization layer can additionally comprise crosslinkable compounds and the crosslinkable compounds can be crosslinked with one another in a further part of the process. The crosslinkable compounds can be polymers having reactive side chains or reactive positions in the main polymer framework which can be crosslinked thermally or photochemically. Crosslinking is optional, with possible crosslinkers being, for example, photo acids. For example, melamine-co-formaldehyde can be used as crosslinker for novolac-type systems. The crosslinking of the crosslinkable compounds can preferably be carried out in the temperature range from 180° C. to 230° C. After crosslinking, particularly mechanically stable planarization layers can be obtained. In addition, the planarization layer is no longer attacked by solvents.

The inventors further propose electrical components having a first electrode layer, a two-layer, dielectric layer comprising a self-assembled monolayer containing phosphoroxo compounds and a planarization layer containing guanidinium compounds and a second electrode layer arranged on top of the dielectric layers. In particular, these components can be thin-film capacitors integrated onto circuit boards or prepregs or integrated transistors. In the case of the transistor, the gate dielectric is formed from the layer described above. The transistor is completed by its further electrodes (source, drain, gate) and by deposition of a semiconductor. These capacitors have a higher integration density (capacitance/area) than the thin-film capacitors described in the related art, are robust and can be produced simply and inexpensively.

In a further aspect, the electronic component can be a storage capacitor in an electronic circuit. The use of the layer can thus not be restricted only to integrated thin-film capacitors. The advantages are thus also obtained in the construction of storage capacitors.

In a further, preferred embodiment, the electronic component can be arranged on a circuit board substrate, a prepreg or a circuit board. In the field of integrated circuits on support substrates in particular, the dielectric layer and the process can lead to particularly effective, long-life components which can be produced inexpensively.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 A potential embodiment of a capacitor according to the inventor's proposals, with the prepreg (1) on which the metal for the lower first electrode (2) with the connection (3) is located.

On the first electrode (2), there is, according to the proposals, the insulating SAM layer (4) containing phosphoroxo compounds onto which the planarization layer (5) containing guanidinium compounds has been applied. The counterelectrode (6) has been applied on top of this. The arrows (7) indicate places at which critical E fields are possible in the capacitor;

FIG. 2 Cyclic voltammogram of the guanidine compounds M7a/b, M8 compared to the reference BMIMPF6;

FIG. 3a Cyclic voltammogram of the guanidine compound K6 compared to the reference BMIMPF6;

FIG. 3b Cyclic voltammogram of the guanidine compound K8 compared to the reference BMIMPF6;

FIG. 4a Cyclic voltammogram of the guanidine compound K2 in acetonitrile and the solvent acetonitrile compared to the reference BMIMPF6;

FIG. 4b Cyclic voltammogram of the guanidine compound K3 in acetonitrile and the solvent acetonitrile compared to the reference BMIMPF6;

FIG. 4c Cyclic voltammogram of the guanidine compound K7 in acetonitrile and the solvent acetonitrile compared to the reference BMIMPF6;

FIG. 4d Cyclic voltammogram of the guanidine compound K9 in acetonitrile and the solvent acetonitrile compared to the reference BMIMPF6;

FIG. 5a Cyclic voltammogram of the guanidine compound K6, K6 in acetonitrile, K6 in anisole and also the solvent acetonitrile;

FIG. 5b Cyclic voltammogram of the solvents acetonitrile, anisole and MEK;

FIG. 6 Cyclic voltammogram of the reference substance BMIMPF6 in anisole and as pure IL and also the solvent anisole;

FIG. 7 Cyclic voltammogram of the guanidine compound K3 dissolved in acetonitrile and in the molten state at 140° C. and also the solvent acetonitrile.

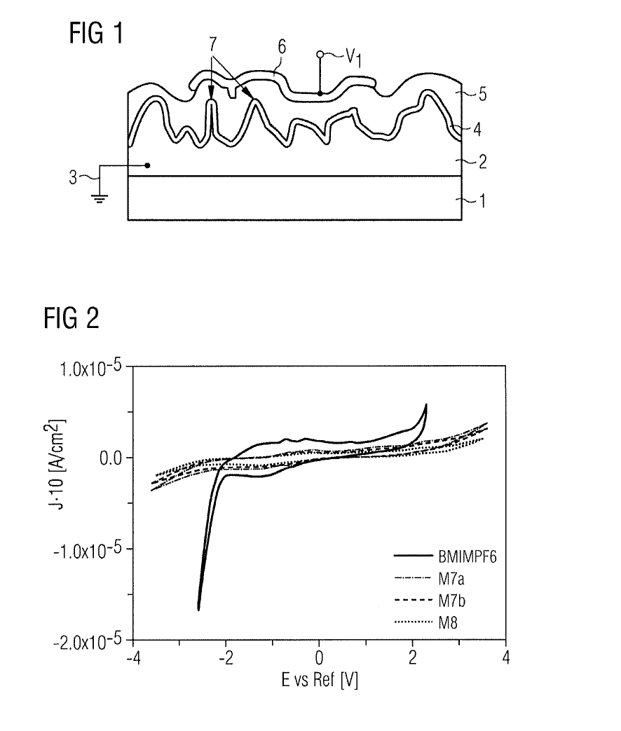

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

### EXAMPLES

### I. Synthesis of the Guanidinium Compounds

### The Synthesis of the Guanidinium Monocations (Compounds of the M Series)

### I.M1 N,N,N′,N′,N″,N″-hexabutylguanidinium trifluoromethanesulfonate

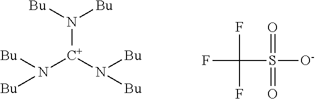

The synthesis and the spectroscopic and physical characterization of the guanidinium compound N,N,N′,N′,N″,N″-hexabutylguanidinium trifluoromethanesulfonate has already been described in H. Kunkel et al., Eur. J. Org. Chem. 2007, 3746-3757.

### I.M2 N,N-Dibutyl-N′,N′,N″,N″-tetramethylguanidinium trifluoromethanesulfonate

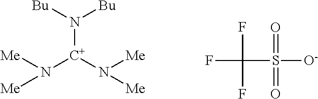

The preparation of N,N-dibutyl-N′,N′,N″,N″-tetramethylguanidinium trifluoromethanesulfonate (I.M2) was carried out from bis(tetramethylamidinio)-ether-bis(trifluoromethanesulfonate) and di-n-butylamine by a general method (H. Kunkel, G. Maas, Eur. J. Org. Chem. 2007, 3746-3757).

Yield: 2.87 g (78%), light-yellow oil. Glass transition temp.: −72° C. The temperature of the maximum decomposition rate (TGA): 456° C. ¹H-NMR (400 MHz, CDCl₃): δ=0.95 (t, 6H, N(CH₂)₃CH₃), 1.25-1.65 (m, 8H, N(CH₂)₂CH₂CH₃ and NCH₂CH₂CH₂CH₃), 2.98 and 3.03 (2 s, each 6H, NCH₃), 3.05-3.22 (m, 4H, NCH₂(CH₂)₂CH₃) ppm. ¹³C-NMR (100 MHz, CDCl₃): δ=13.7 (N(CH₂)₃CH₃), 20.0 (N(CH₂)₂CH₂CH₃), 29.6 (NCH₂CH₂CH₂CH₃), 40.4 (NCH₃) 49.3 (NCH₂(CH₂)₂CH₃), 163.3 (CN₃) ppm. ¹⁹F-NMR (376 MHz, CDCl₃): δ=−74.7 ppm. IR (NaCl): ν=2962 (s), 2936 (s), 2876 (m), 1593 (s), 1568 (s), 1464 (m), 1435 (m), 1411 (m), 1268 (s), 1224 (m), 1150 (s), 1032 (s) cm⁻¹. Analysis, calc. for C₁₄H₃₀F₃N₃O₃S (377.47): C, 44.55; H, 8.01; N, 11.13%. found: C, 44.59; H, 8.49; N, 11.15%.

### I.M3 N,N-Dibutyl-N′,N′,N″,N″-tetramethylguanidinium bis(trifluoromethylsulfonyl)imide

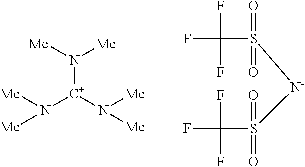 [SMILES: CN(C)[C+](N(C)C)N(C)C ; O=S(=O)([N-]S(=O)(=O)C(F)(F)F)C(F)(F)F]

The synthesis and the spectroscopic and physical characterization of the guanidinium compound N,N-dibutyl-N′,N′,N″,N″-tetramethylguanidinium bis(trifluoromethylsulfonyl)imide has already been described in S. Fang, L. Yang, C. Wei, C. Jiang, K. Tachibana, K. Kamijima, Electrochimica Acta 2009, 54, 1752-1756.

### I.M4 N,N-Dibutyl-N′,N′,N″,N″-tetramethylguanidinium bis(trifluoromethylsulfonyl)imide

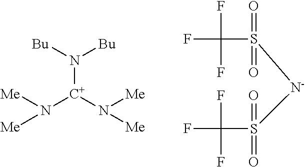

The synthesis and the spectroscopic and physical characterization of the guanidinium compound have already been described in S. Fang, L. Yang, C. Wei, C. Jiang, K. Tachibana, K. Kamijima, Electrochimica Acta 2009, 54, 1752-1756 and WO2005075413 A1.

### I.M5 N,N,N′,N′-Tetramethyl-N″,N″-pentamethyleneguanidinium bis(trifluoromethylsulfonyl)imide

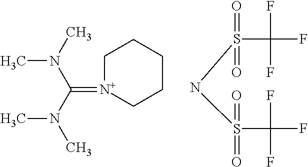

N,N,N′,N′-Tetramethyl-N″,N″-pentamethyleneguanidinium bis(tri-fluoromethylsulfonyl)imide was prepared by anion exchange from N,N,N′,N′-tetramethyl-N″,N″-pentamethyleneguanidinium chloride using the method of M. Walter et al., Z. Naturforsch. 2009, 64b, 1617-1624. A solution of 2.9 g (10 mmol) of lithium bis(trifluoromethylsulfonyl)imide in water (10 ml) was added to a solution of 2.2 g (10 mmol) of N,N,N′,N′-tetramethyl-N″,N″-pentamethyleneguanidinium chloride in water (30 ml), with two phases being formed. The mixture was stirred at 70° C. for 30 minutes, cooled to room temperature and admixed with dichloromethane (30 ml). The organic phase was washed with portions of 10 ml of water in each case until the chloride test using silver nitrate was negative. The organic phase was dried over sodium sulfate, the solvent was removed and the product was dried at 100° C./0.05 mbar for 8 hours. To achieve complete decoloration of the product, its solution in dichloromethane can be stirred for 15 minutes with addition of activated carbon. Yield: 4.4 g (95%), light-yellowish oil, m.p. 3° C. Temperature of the maximum decomposition rate (TGA): 470° C. ¹H-NMR (400 MHz, CDCl₃): δ=1.65-1.80 (m, 6H, CH₂(CH₂)₃CH₂, Pip), 2.98 and 2.99 (2 s, each 6H, NCH₃), 3.20-3.35 (m, 4H, NCH₂, Pip) ppm. ¹³C-NMR (100 MHz, CDCl₃): δ=23.4 (N(CH₂)₂CH₂, Pip), 25.1 (NCH₂CH₂CH₂, Pip), 40.32 and 40.35 (NCH₃), 49.9 (NCH₂CH₂CH₂, Pip), 162.8 (CN₃) ppm ¹⁹F-NMR (376 MHz, CDCl₃): δ=−75.3 ppm. IR (NaCl): ν=2951 (m), 2864 (m), 1569 (s), 1411 (m), 1347 (s), 1330 (s), 1176 (s), 1134 (s), 1053 (s) cm⁻¹, MS (Cl): m/e=184 (100%, [cation]⁺). Analysis, calc. for C₁₂H₂₂F₆N₄O₄S₂ (464.44): C, 31.03; H, 4.77; N, 12.06%. found: C, 31.03; H, 4.68; N, 12.25%.

### I.M6 N,N,N′,N′-Tetramethyl-N″,N″-pentamethyleneguanidinium tetrafluoroborate

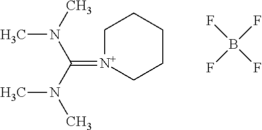

As described by M. Walter et al., Z. Naturforsch. 2009, 64b, 1617-1624, 1.4 g (12.7 mmol) of sodium tetrafluoroborate were added to a solution of 2.0 g (9.1 mmol) of N,N,N′,N′-tetramethyl-N″,N″-pentamethyleneguanidinium chloride in dry dichloromethane (25 ml). The suspension was stirred at room temperature under an argon atmosphere for 24 hours. The colorless precipitate was filtered off, the solvent was removed and the solid product was dried at 80° C./0.05 mbar for 8 hours. To decolorize the salt, its solution in dichloromethane can be stirred with activated carbon for 15 minutes. Yield: 2.3 g (94%), colorless solid, m.p. 107-108° C. Temperature of the maximum decomposition rate (TGA): 468° C. ¹H-NMR (400 MHz, CDCl₃): δ=1.67-1.77 (m, 6H, CH₂(CH₂)₃CH₂, Pip), 2.98 and 2.99 (2 s, each 6H, NCH₃), 3.25-3.33 (m, 4H, NCH₂, Pip) ppm. ¹³C-NMR (100 MHz, CDCl₃): δ=23.5 (N(CH₂)₂CH₂, Pip), 25.2 (NCH₂CH₂CH₂, Pip), 40.32 and 40.36 (NCH₃), 49.9 (NCH₂CH₂CH₂, Pip), 163.0 (CN₃) ppm. ¹⁹F-NMR (376 MHz, CDCl₃): δ=−149.97, −150.02 ppm. IR (ATR): ν=2938 (m), 2868 (m), 1569 (s), 1412 (m), 1277 (m), 1093 (m), 1070 (m), 1033 (s) cm⁻¹. Analysis, calc. for C₁₀H₂₂BF₄N₃ (271.11): C, 44.30; H, 8.18; N, 15.50%. found: C, 44.18; H, 8.28; N, 15.35%.

### I.M7 N,N-Dihexyl-N′,N′-dimethyl-N″,N″-pentamethyleneguanidinium tetrafluoroborate

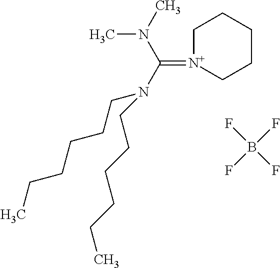

The basic synthesis of N,N-dihexyl-N′,N′-dimethyl-N″,N″-pentamethyleneguanidinium tetrafluoroborate has already been described in Sheng-hai Li et al., Chem. Res. Chin. Univ. 2005, 21, 158-162.

A description is given of a synthesis which is modified in comparison with the literature and in which an anion exchange is carried out on a guanidinium chloride instead of a guanidinium bromide. A comprehensive spectroscopic and analytical characterization and also two different batch results (a+b) are likewise reported.

a) N,N-Dihexyl-N′,N′-dimethyl-N″,N″-pentamethyleneguanidinium chloride: A solution of di-n-hexylamine (4.6 ml, 20 mmol) and triethylamine (2.8 ml, 20 mmol) in anhydrous dichloromethane (10 ml) was slowly added dropwise at 0° C. to a suspension of N,N-dimethylphosgeniminium chloride (3.25 g, 20 mmol) in dry dichloromethane (40 ml) while stirring. After stirring at RT for 1 hour, a solution of piperidine (2.0 ml, 20 mmol) and triethylamine (2.8 ml, 20 mmol) in anhydrous dichloromethane (10 ml) is added dropwise at 0° C. while stirring. The mixture was stirred at room temperature for another 3 hours and the precipitated solid (triethylammonium chloride) was filtered off. After removal of the solvent, 0.1 M NaOH was added to the residue until the pH was weakly basic. To remove colored impurities, the aqueous phase was washed three times with 15 ml each time of diethyl ether. The aqueous phase was saturated with sodium chloride and extracted three times with 15 ml each time of dichloromethane. The organic phases were combined and dried over sodium sulfate, and the solvent was removed. The product was dried at 40° C./0.05 mbar for 6 hours. Yield: 5.0 g (70%), orange oil. Glass transition temp.: −52° C. Temperature of the maximum decomposition rate (TGA): 296° C. ¹H-NMR (400 MHz, CDCl₃): δ=0.87 (t, 6H, N(CH₂)₅CH₃), 1.17-1.85 (plurality of m, 22H, NCH₂(CH₂)₄CH₃ and CH₂(CH₂)₃CH₂, Pip), 3.07 and 3.19 (2 s, each 3H, NCH₃), 3.13-3.67 (plurality of m, 8H, NCH₂(CH₂)₄CH₃ and NCH₂, Pip) ppm. ¹³C-NMR (100 MHz, CDCl₃): 6=13.9 (N(CH₂)₅CH₃), 22.44 and 22.47 (N(CH₂)₄CH₂CH₃), 23.4 (N(CH₂)₂, Pip), 25.26 and 25.30 (NCH₂CH₂CH₂, Pip), 26.38 and 26.50 (N(CH₂)₃CH₂CH₂CH₃), 27.57 and 27.69 (N(CH₂)₂(CH₂)₂CH₃), 31.31 and 31.36 (NCH₂CH₂(CH₂)₃CH₃), 40.9 and 41.2 (NCH₃), 49.6 and 49.7 (NCH₂(CH₂)₄CH₃), 50.2 and 50.4 (NCH₂CH₂CH₂, Pip), 162.8 (CN₃) ppm. IR (NaCl): ν=2933 (s), 2858 (s), 1585 (s), 1546 (s), 1452 (m), 1420 (m), 1255 (m) cm⁻¹. MS (Cl): m/e=324 (100%, [cation]⁺). Analysis, calc. for C₂₀H₄₂C1N₃×0.66H₂O (360.02); C, 64.57; H, 11.74; N, 11.29%. found: C, 64.66; H, 11.86; N, 11.38%.

b) The anion exchange was carried out in a manner analogous to the method for I.M6, using 1.0 g (2.9 mmol) of N,N-dihexyl-N′,N′-dimethyl-N″,N″-pentamethyleneguanidinium chloride and 0.44 g (4.0 mmol) of sodium tetrafluoroborate. Yield: 0.93 g (79%), yellowish viscous oil. Glass transition temp.: −59° C. Temperature of the maximum decomposition rate (TGA): 472° C. ¹H-NMR (400 MHz, CDCl₃): δ=0.89 (t, 6H, N(CH₂)₅CH₃), 1.17-1.80 (plurality of m, 22H, NCH₂(CH₂)₄CH₃ and CH₂(CH₂)₃CH₂, Pip), 2.97 and 3.03 (2 s each 3H, NCH₃), 3.00-3.45 (plurality of m, 8H, NCH₂(CH₂)₄CH₃ and NCH₂, Pip) ppm. ¹³C-NMR (100 MHz. CDCl₃): δ=13.9 (N(CH₂)₅CH₃), 22.49 and 22.50 (N(CH₂)₄CH₂CH₃), 23.5 (N(CH₂)₂CH₂, Pip), 25.1 and 25.2 (NCH₂CH₂CH₂, Pip), 26.37 and 26.52 (N(CH₂)₂CH₂(CH₂(CH₂)₂CH₃), 31.33 and 31.37 (NCH₂CH₂(CH₂)₃CH₃), 40.49 and 40.51 (NCH₃), 49.4 and 49.6 (NCH₂(CH₂)₄CH₃), 50.0 and 50.1 (NCH₂CH₂CH₂, Pip), 163.0 (CN₃) ppm. ¹⁹F-NMR (376 MHz, CDCl₃): δ=−150.05, −150.10 ppm. IR (NaCl): ν=2933 (s), 2860 (m), 1583 (s), 1549 (s), 1455 (m), 1423 (m), 1284 (m), 1255 (m), 1055 (s) cm⁻¹. MS (Cl): m/e=324 (100%, [cation]⁺). Analysis, calc. for C₂₀H₄₂BF₄N₃ (411.37): C, 58.39; H, 10.29; N, 10.21%. found: C, 58.67; H, 10.49; N, 10.13%.

### I.M8 N,N-Dihexyl-N′,N′-dimethyl-N″,N″-pentamethyleneguanidinium hexafluorophosphate

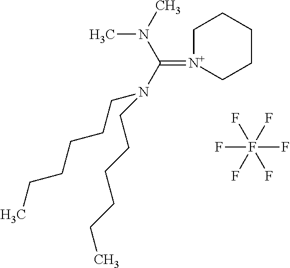

The basic synthesis of N,N-dihexyl-N′,N′-dimethyl-N″,N″-pentamethyleneguanidinium hexafluorophosphate has been described in Sheng-hai Li et al., Chem. Res. Chin. Univ. 2005, 21, 158-162.

1.5 g (8.4 mmol) of potassium hexafluorophosphate were added to a solution of 2.15 g (6.0 mmol) of N,N-dihexyl-N′,N′-dimethyl-N″,N″-pentamethyleneguanidinium chloride (see at I.7) in dry dichloromethane (25 ml). The suspension was stirred at RT under an argon atmosphere for 24 hours. The white precipitate was filtered off and the solvent was removed. The product was dried at 80° C./0.05 mbar for 8 hours. To decolorize the slightly yellowish salt, its dichloromethane solution can be stirred with activated carbon for 15 minutes. Yield: 2.4 g (86%), yellowish viscous oil. Glass transition temp.: −55° C. Temperature of the maximum decomposition rate (TGA): 466° C. ¹H-NMR (400 MHz, CDCl₃): δ=0.89 (t, 6H, N(CH₂)₅CH₃), 1.17-1.82 (plurality of m, 22H, NCH₂(CH₂)₄CH₃ and CH₂(CH₂)₃CH₂, Pip), 2.95 and 3.00 (2 s, each 3H, NCH₃), 3.00-3.40 (plurality of m, 8H, NCH₂(CH₂)₄CH₃ and NCH₂, Pip) ppm. ¹³C-NMR (100 MHz, CDCl₃): δ=13.9 (N(CH₂)₅CH₃), 22.47 and 22.49 (N(CH₂)₄CH₂CH₃), 23.4 (N(CH₂)₂CH₂, Pip), 25.1 and 25.2 (NCH₂CH₂CH₂, Pip), 26.3 and 26.5 (N(CH₂)₃(CH₂CH₂CH₃), 27.4 and 27.5 (N(CH₂)₂CH₂(CH₂)₂CH₃), 31.31 and 31.35 (NCH₂CH₂(CH₂)₃CH₃), 40.46 (NCH₃), 49.5 and 49.7 (NCH₂(CH₂)₄CH₃), 50.0 and 50.1 (NCH₂CH₂CH₂, Pip), 162.9 (CN₃) ppm. ¹⁹F-NMR (376 MHz, CDCl₃): δ=−68.8, −70.7 ppm. IR (NaCl): ν=2933 (s), 2861 (m), 1581 (s), 1553 (s), 1455 (m), 1424 (m), 1286 (m), 1255 (m), 1026 (m) cm⁻¹. MS (Cl): m/e=324 (100%, [cation]⁺). Analysis, calc. for C₂₀H₄₂F₆N₃P (469.53): C, 51.16; H, 9.02; N, 8.95%. found: C, 51.32; H, 9.08; N, 8.97%.

Synthesis of the Guanidinium Dications and Guanidinium Betaine Compounds (K Series)

Method for the Synthesis of General Intermediates and Precursors of this Class of Compounds:

For the synthesis of the following compounds, pentaalkylated guanidines are used as synthesis precursors. The synthesis of these precursors is carried out according to a literature method (Zeitschrift für Naturforschung, B:(2010), 65, (7), 873-906).

An equimolar mixture of the respective primary amine and triethylamine is added dropwise to a solution of the appropriate tetraalkylchloroformamidinium chloride in acetonitrile (1 mol in 700 ml of solvent) while cooling in ice and stirring vigorously, the mixture is stirred for 16 hours and then heated under reflux for 2 hours. The mixture is stirred at room temperature for another 1 hour and the volatile constituents are then removed under reduced pressure on a rotary evaporator. About as many gram of water as are present in the residue is added to the salt mixture obtained, the mixture is covered with diethyl ether and 2.0 equivalents of sodium hydroxide solution (1 mol in 75 ml of water) are then added while stirring vigorously. The mixture is subsequently stirred for 1 hour, the organic phase is separated off after 30 minutes, washed three times with water and dried over sodium sulfate. The solution obtained is evaporated on a rotary evaporator and subsequently either recrystallized from a suitable solvent or fractionally distilled via a 30 cm Vigreux column.

### I.G1 N,N,N′,N′-Tetramethyl-N″-[2-(N,N,N′,N′-tetramethylguanidino)ethyl]guanidine

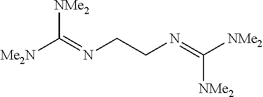 [SMILES: CN(C)C(=NCCN=C(N(C)C)N(C)C)N(C)C]

### Batch:

| | | |
|---|---|---|
| N,N,N′,N′-Tetramethylchloroformamidinium chloride | 0.3 mol | 51.3 g |
| (171.07 g/mol) | | |
| 1,2-Diaminoethane (60.10 g/mol) | 0.15 mol | 9.0 g |
| Triethylamine (101.19 g/mol) | 0.3 mol | 30.4 g |
| NaOH (40.00 g/mol) | 0.6 mol | 24.0 g |

Recrystallization from acetonitrile gives colorless crystals of N,N,N′,N′-tetramethyl-N″-[2-(N,N,N′,N′-tetramethylguanidino)ethyl]guanidine. Yield: 25.9 g (67%).

It is notable in the ¹NMR spectrum of this compound that the N-methyl signals appear at a very high field. The measurement was carried out in C₆D₆.

m.p. 112-113° C.—IR (ATR): ν=1590 (C═N) (cm⁻¹).—¹H NMR (500.1 MHz, C₆D₆): 6=1.67, 1.69 (each s, each 12H, NCH₃), 2.89 (s, 4H, CH₂).—¹³C NMR (125.8 MHz, C₆D₆): δ=39.29, 39.55 (NCH₃), 53.68 (CH₂), 158.85 (C═N).—C₁₂H₂₈N₆ (256.39): calc. C, 56.21; H, 11.01; N, 32.78. found C, 56.19; H, 10.91; N, 32.81.

### I.G2 N,N-Diethyl-N′,N′-dipropyl-N″-[2-(N,N-diethyl-N′,N′-dipropylylguanidino)ethyl]guanidine

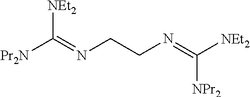

### Batch:

| | | |
|---|---|---|
| N,N-Dibutyl-N′,N′-dipropylchloroformamidinium | 0.3 mol | 76.6 g |
| chloride (255.23 g/mol) | | |
| 1,2-Diaminoethane (60.10 g/mol) | 0.15 mol | 9.0 g |
| Triethylamine (101.19 g/mol) | 0.3 mol | 30.4 g |
| NaOH (40.00 g/mol) | 0.6 mol | 24.0 g |

Fractionation gives N,N-diethyl-N′,N′-dipropyl-N″-[2-(N,N-diethyl-N′,N′-dipropylylguanidino)ethyl]guanidine as a yellowish oil. Yield: 43.5 g (68%).

b.p. 158-160° C./10⁻³ Torr.—n_{D}²⁰=1.4841.=IR (ATR): ν=1602 (C═N) (cm⁻¹).—¹H NMR (500.1 MHz, CDCl₃): δ=0.811-0.85 (m, 12H, NCH₂CH₂CH₃), 1.00-1.04 (m, 12H, NCH₂CH₃), 1.44-1.49 (m, 8H, NCH₂CH₂CH₃), 2.92-2.96 (m, 4H, NCH₂), 3.09-3.14 (m, 12H, NCH₂), 2.27-3.32 (m, 4H, NCH₂).—¹³C NMR (125.8 MHz, CDCl₃): δ=11.51, 11.64, 12.86, 12.89, 13.52, 13.56 (CH₃), 20.83, 20.85, 21.63, 21.67 (CH₂), 41.48, 41.67, 42.45, 49.56, 49.70, 50.97, 51.01, 53.00 (NCH₂), 158.54, 158.65, 159.03 (C═N)—C₂₄H₅₂N₆ (424.71): calc. C, 67.87; H, 12.34; N, 19.79. found C, 67.98; H, 12.12; N, 19.73.

### I.V1 N-Butyl-N′,N′,N″,N″-tetramethyl-N-[2-(N-butyl-N′,N′,N″,N″-tetramethylguanidino)ethyl]guanidinium dichloride

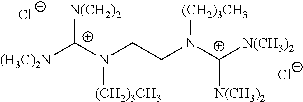

Batch:

| | | |
|---|---|---|
| N,N,N′,N′-Tetramethyl-N″-[2-(N,N,N′,N′- | 0.05 mol | 12.8 g |
| tetramethylguanidino)ethyl]guanidine (G1) | | |
| (256.39 g/mol) | | |
| n-Butyl chloride (92.57 g/mol) | 0.13 mol | 12.0 g |

12.8 g (0.05 mol) of N,N,N′,N′-tetramethyl-N″-[2-(N,N,N′,N′-tetramethylguanidino)ethyl]guanidine are dissolved in 100 ml of dimethylformamide and admixed with 12.0 g (0.13 mol) of n-butyl chloride. After stirring at 90° C. for 24 hours, the solvent is removed under reduced pressure on a rotary evaporator. The residue is recrystallized from ethylene glycol dimethyl ether and crude N-butyl-N′,N′,N″,N″-tetramethyl-N-[2-(N-butyl-N′,N′,N″,N″-tetramethylguanidino)ethyl]guanidinium dichloride is obtained as a colorless, strongly hygroscopic powder. Yield: 3.28 g (67%).

This product was not obtained in pure form according to elemental analysis.

m.p. 169-171° C., decomposition from 230° C.—IR (ATR): ν=1610, 1552 (C═N⁺) (cm⁻¹).

### I.V2 N,N-Diethyl-N′,N′-dipropyl-N″-methyl-N″-[2-(N,N-diethyl-N′,N′-dipropylyl-N″-methylguanidino)ethyl]guanidinium bis(methylsulfate)

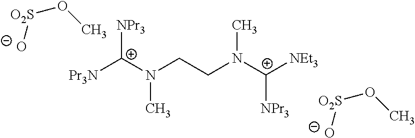

| | | |
|---|---|---|
| N,N-Diethyl-N′,N′-dipropyl-N″-[2-(N,N-diethyl- | 30 mmol | 12.7 g |
| N′,N′-dipropylylguanidino)ethyl]guanidine (G2) | | |
| (424.71 g/mol) | | |
| Dimethyl sulfate (126.13 g/mol) | 60 mmol | 7.6 g |

12.7 g (30 mmol) of N,N-diethyl-N′,N′-dipropyl-N″[2-(N,N-diethyl-N′,N′-dipropylylguanidino)ethyl]guanidine are dissolved in 100 ml of acetonitrile and admixed at 0° C. with 7.6 g (60 mmol) of dimethyl sulfate. After stirring at RT for 24 hours, the solvent is removed under reduced pressure on a rotary evaporator. The residue is recrystallized from ethylene glycol dimethyl ether and N,N-diethyl-N′,N′-dipropyl-N″-methyl-N″-[2-(N,N-diethyl-N′,N′-dipropylyl-N″-methylguanidino)ethyl]guanidinium bis(methylsulfate) is obtained as a colorless powder. Yield: 16.9 g (83%).

m.p. 126-127° C.—IR (ATR): ν=1544 (C═N⁺) (cm⁻¹).—¹H NMR (500.1 MHz, CD₃CN): δ=0.86-0.95 (m, 12H, NCH₂CH₂CH₃), 1.13-1.24 (m, 12H, NCH₂CH₃), 1.38-1.61, 1.63-1.96 (each m, each 4H, NCH₂CH₂CH₃), 2.92-3.71 (m, 32H, NCH₂, NCH₃, OCH₃).—¹³C NMR (125.8 MHz, CD₃CN): δ=10.21, 10.37, 11.60, 11.74, 11.91, 12.02, 12.09 (CH₃), 20.09, 20.29, 20.34, 20.38, 20.43, 20.54 (CH₂), 37.72, 37.76, 37.80, 37.87, 37.93 (NCH₃), 43.28, 43.39, 43.51, 43.91, 44.01, 48.86, 48.93, 49.00, 40.05, 50.67, 50.74, 50.88, 50.96, 51.21, 51.31 (NCH₂), 52.70 (OCH₃), 164.15, 164.20 (C⁺).—C₂₈H₆₄N₆O₈S₂ (676.42): calc. C, 49.68; H, 9.53; N, 12.41; S, 9.47. found C, 49.46; H, 9.50; N, 12.54; S, 9.61.

Synthesis of the Zwitterionic Guanidinium Precursors 1-3

The guanidines 1-4 required as starting materials have already been described in W. Kantlehner, J. Mezger, R. Kreβ, H. Hartmann, T. Moschny, I. Tiritiris, B. Iliev, O. Scherr, G. Ziegler, B. Souley, W. Frey, I. C. Ivanov, M. G. Bogdanov, U. Jäger, G. Dospil, T. Viefhaus, Z. Naturforsch. 210, 656, 873-906.

The guanidines

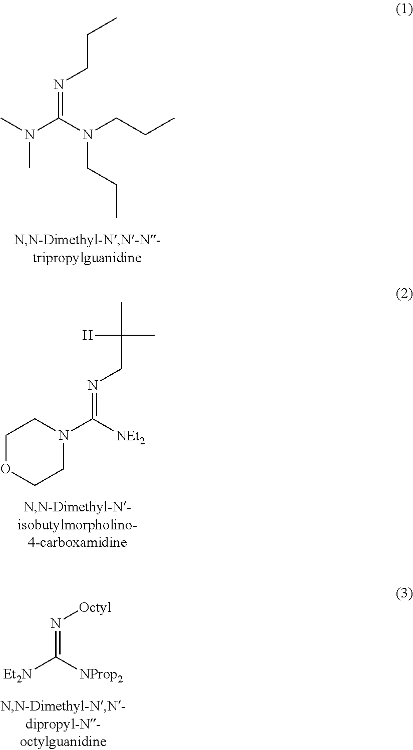

are used as starting materials for the further synthesis.

General Method:

Reaction of various guanidines with 1,3-propane sultone or 1,4-butane sultone.

0.10 mol of the sultone dissolved in 50 ml of acetonitrile is added dropwise to a solution of 0.03 mol of the guanidine in 30 ml of acetonitrile. The mixture is then heated under reflux (about 80° C.) for 12 hours. The solvent is removed and the crude product is washed 3 times with diethyl ether. The product is subsequently dried in an oil pump vacuum for a plurality of hours.

### I.K1 N-Butyl-N′,N′,N″,N″-tetramethyl-N-[2-(N-butyl-N′,N′,N″,N″-tetramethylguanidino)ethyl]guanidinium (bis)trifluoromethanesulfonate

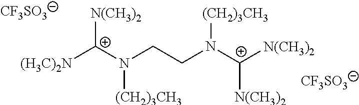

| | | |
|---|---|---|
| N-Butyl-N′,N′,N″,N″-tetramethyl-N-[2- | 10 mmol | 4.4 g |
| (N-butyl-N′,N′,N″,N″- | | |
| tetramethylguanidino)ethyl]guanidinium dichloride | | |
| (V.1) (441.53 g/mol) | | |
| Trifluoromethanesulfonic acid (150.08 g/mol) | 20 mmol | 3.0 g |

4.4 g (10 mol) of N-butyl-N′,N′,N″,N″-tetramethyl-N-[2-(N-butyl-N′,N′,N″,N″-tetramethylguanidino)ethyl]guanidinium dichloride (I.V1) are dissolved in 50 ml of water and subsequently admixed with 3.0 g (20 mmol) of trifluoromethanesulfonic acid in 20 ml of water. After stirring at room temperature for 30 minutes, the reaction mixture is evaporated on a rotary evaporator, admixed with 100 ml of water and, after stirring for 2 hours, the precipitate is filtered off with suction and subsequently recrystallized from ethylene glycol dimethyl ether. This gives N-butyl-N′,N′,N″,N″-tetramethyl-N-[2-(N-butyl-N′,N′,N″,N″-tetramethylguanidino)-ethyl]guanidinium (bis)trifluoromethanesulfonate as colorless crystals. Yield: 5.6 g (85%).

m.p. 126° C.—IR (ATR): ν=1600, 1553 (C═N⁺) (cm⁻¹).—¹H NMR (500.1 MHz, CD₃CN): δ=0.93 (t, 6H, J=7.3 Hz, butyl-CH₃), 1.27-1.69 (m, 8H, butyl-CH₂), 2.91, 2.93 (each s, 24H, NCH₃), 3.05-3.52 (m, 8H, NCH₂).—¹³C NMR (125.8 MHz, CD₃CN): δ=12.54 (CH₃), 19.06, 28.92, 29.12 (butyl-CH₂), 38.98, 39.35, 39.61 (NCH₃), 42.18 45.71, 47.28, 48.79 (NCH₂), 116.88, 119.39, 121.94, 124.49 (CF₃), 162.97 (C⁺).—C₂₂H₄₆F₆N₆O₆S₂(668.76): calc. C, 39.51; H, 6.93; N, 12.57; S, 9.59. found C, 39.56; H, 6.96; N, 12.58; S, 9.33.

### I.K2 3-(N,N,N′,N′,N″-Pentamethylguanidinio)propanesulfonate

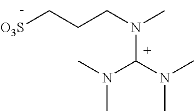

The compound which is already known from the literature (Z. Naturforsch. 2010, 65b, 873-906) was prepared by the above general method from pentamethylguanidine and 1,3-propane sultone in acetonitrile.

3.88 g (0.03 mol) of N,N,N′,N′,N″-pentamethylguanidine gives 6.92 g (91.8%) of 3-(N,N,N′,N′,N″-pentamethylguanidinio)propanesulfonate (I.K2).

Colorless solid, m.p.: 263-268° C.—¹H NMR (500 MHz, D20): δ=1.84-2.08 (m, 2H, CH₂), 2.45-2.55 (m, 2H, CH₂), 2.87-2.95 (s, 15H, NMe₂), 3.10-3.55 (m, 2H CH₂).—¹³C NMR (125 MHz, D₂O): δ=23.3 (CH₂), 36.5 (NMe₂), 38.5 (NMe₂), 39.20 (NMe₂), 47.2 (CH₂), 50.6 (CH₂), 163.2 (N₃C⁺).—C9H21N3O3S (251.35): calc. C, 43.01; H, 8.42; N, 16.72; S, 12.76. found C, 42.94; H, 8.33; N, 16.53; S, 12.55.

### I.K3 3-(N,N-Dimethyl-N′,N′,N″-tripropylguanidinio)propanesulfonate

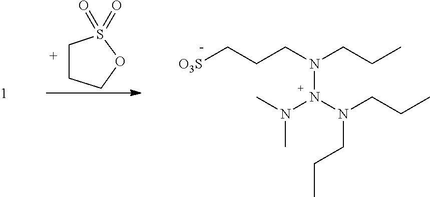

6.4 g (0.03 mol) of N,N-dimethyl-N′,N′,N″-tripropylguanidine (1) gives 9.59 g (95.2%) of 3-(N,N-dimethyl-N′,N′,N″-tripropylguanidinio)propanesulfonate (K3): colorless solid; m.p.: 124-126° C. ¹H NMR (500 MHz, D₂O): δ=0.96-1.00 [m, 9H (CH₃), 1.43-1.65 (m, 6H, CH₂), 1.70-1.98 (m, 6H, CH₂), 2.85 (s, 6H, NMe₂), 2.95-3.33 (m, 6H, CH₂).—¹³C NMR (125 MHz, D₂O): δ=11.4 (CH₃), 20.8-23.2 (CH₂), 23.9-26.8 (CH₂), 40.0-41.0 (NMe₂), 50.0-51.5 (CH₂), 163.1 (N₃C⁺).—C₁₅H₃₃N₃O₃S (335.51): calc. C, 53.70; H, 9.91; N, 12.52; S, 9.56. found C, 53.57; H, 9.85; N, 12.36; S, 9.49.

### I.K4 N-Butyl-N′,N′,N″,N″-tetramethyl-N-[2-(N-butyl-N′,N′,N″,N″-tetramethylguanidino)ethyl]guanidinium bis(hexafluorophosphate)

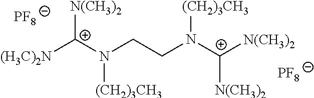

| | | |
|---|---|---|
| N-Butyl-N′,N′,N″,N″-tetramethyl- | 10 mmol | 4.4 g |
| N-[2-(N-butyl-N′,N′,N″,N″- | | |
| tetramethylguanidino)ethyl]guanidinium dichloride | | |
| (I.V1) (441.53 g/mol) | | |
| Sodium hexafluorophosphate (167.95 g/mol) | 20 mmol | 3.4 g |

4.4 g (10 mmol) of N-butyl-N′,N′,N″,N″-tetramethyl-N-[2-(N-butyl-N′,N′,N″,N″-tetramethylguanidino)ethyl]guanidinium dichloride (V1) are dissolved in 50 ml of acetonitrile and subsequently admixed with 3.4 g (20 mmol) of sodium hexafluorophosphate. After stirring at room temperature for 40 hours, the reaction mixture is filtered, then evaporated on a rotary evaporator, admixed with 100 ml of water, stirred for 2 hours and the precipitate is then filtered off with suction and subsequently recrystallized from ethylene glycol dimethyl ether. This gives N-butyl-N′,N′,N″,N″-tetramethyl-N-[2-(N-butyl-N′,N′,N″,N″-tetramethylguanidino)ethyl]guanidinium bis(hexafluorophosphate) (I.K4) as colorless crystals. Yield: 5.6 g (85%).

m.p. 177-178° C.—IR (ATR): ν=1598, 1555 (C═N+) (cm⁻¹).—1H NMR (500.1 MHz, CD3CN): δ=0.97 (t, 6H, J=7.3 Hz, butyl-CH3), 1.29-1.69 (m, 8H, butyl-CH2), 2.93, 2.95 (each s, 24H, NCH3), 3.05-3.49 (m, 8H, NCH2). -13C NMR (125.8 MHz, CD3CN): δ=12.74 (CH3), 19.28, 29.31 (butyl-CH2), 39.17, 39.49, 39.72 (NCH3), 42.29 45.90, 47.44, 48.92 (NCH2), 161.14, 163.19 (C+).—C20H46F12N6P2 (660.54): calc. C, 36.37; H, 7.02; N, 12.72. found C, 36.35; H, 6.76; N, 12.67.

### I.K5 N-Ethyl-N′,N′,N″,N″-tetramethyl-N-[2-(N-ethyl-N′,N′,N″,N″-tetramethylguanidino)ethyl]guanidinium bis(tetrafluoroborate)

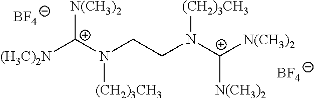

Batch:

| | | |
|---|---|---|
| N,N,N′,N′-Tetramethyl-N″-[2- | 10 mmol | 2.56 g |
| (N,N,N′,N′-tetramethylguanidino)ethyl]guanidine (I.G.1) | | |
| (256.39 g/mol) | | |
| Triethyloxonium tetrafluoroborate (189.99 g/mol) | 20 mmol | 3.8 g |

2.56 g (10 mmol) of N,N,N′,N′-tetramethyl-N″-[2-(N,N,N′,N′-tetramethylguanidino)ethyl]guanidine (I.G1) are dissolved in 100 ml of diethyl ether and admixed at 0° C. with 3.8 g (20 mmol) of triethyloxonium tetrafluoroborate. After stirring at 20° C. for 24 hours, the solvent is removed under reduced pressure on a rotary evaporator, the residue is admixed with 50 ml of water and extracted three times with 50 ml each time of methylene chloride. The combined organic phases are dried over sodium sulfate, filtered and evaporated on a rotary evaporator. The residue is recrystallized from pentanone/acetone (50:1) and N-ethyl-N′,N′,N″,N″-tetramethyl-N-[2-(N-ethyl-N′,N′,N″,N″-tetramethylguanidino)ethyl]guanidinium bis(tetrafluoroborate) (K5) is obtained as colorless crystals. Yield: 3.28 g (67%).

m.p. 209-210° C.—IR (ATR): ν=1602, 1552 (C═N⁺) (cm⁻¹).—¹H NMR (500.1 MHz, CD₃CN): δ=1.13-1.21 (m, 6H, CH₃), 2.91, 2.93 (each s, 24H, NCH₃), 3.05-3.58 (m, 8H, NCH₂).—¹³C NMR (125.8 MHz, CD₃CN): δ=12.15, 12.33 (CH₃), 39.11, 39.36 (NCH₃), 42.28 43.92, 44.04, 45.43, 46.83 (NCH₂), 161.37, 163.18 (C⁺).—C16H38B2F8N6 (488.12): calc. C, 39.37; H, 7.85; N, 17.22. found C, 39.10; H, 7.85; N, 17.17.

### I.K6 4-(N,N-Dimethyl-N′,N′,N″-tripropylguanidinio)butanesulfonate

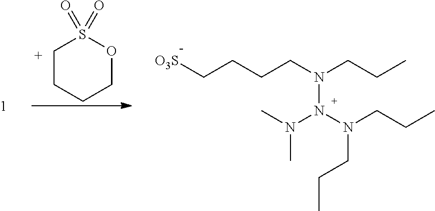

6.4 g (0.03 mol) of N,N-dimethyl-N′,N′,N″-tripropylguanidine (1) give 9.70 g (92.5%) of 4-(N,N-dimethyl-N′,N′,N″-tripropylguanidinio)butanesulfonate (I.K6):

light-yellow viscous mass.—1H NMR (500 MHz, D2O): δ=0.95-0.97 [m, 9H, (CH3), 1.40-1.60 (m, 6H, CH2), 1.65-1.95 (m, 6H, CH2), 2.83 (s, 6H, NMe2), 2.97-3.35 (m, 8H, CH2).—13C NMR (125 MHz, D2O): δ=11.2 (CH3), 20.6-22.8 (CH2), 23.5-26.5 (CH2), 40.0-41.0 (NMe2), 50.2-51.7 (CH2), 163.4 (N3C+).—C16H35N3O3S (349.53): calc. C, 54.98; H, 10.09; N, 12.02; S, 9.17. found C, 54.77; H, 9.98; N, 11.94; S, 9.07.

### I.K7 3-(N,N,N′,N′-Tetramethyl-N″-ethylguanidinio)propanesulfonate

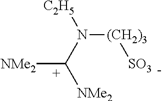

The compound which is already known from the literature (Z. Naturforsch. 2010, 65b, 873-906) was prepared by the above general method from N,N,N′,N′-tetramethyl-N″-ethylguanidine and 1,3-propane sultone in acetonitrile.

4.30 g (0.03 mol) of N,N,N′,N′-tetramethyl-N″-ethylguanidine give 6.15 g (78%) of 3-(N,N,N′,N′-tetramethyl-N″-ethylguanidinio)propanesulfonate (K7):

colorless solid having an m.p. of 253° C.—¹H-NMR (500 MHz, CD₃CN): δ=1.14 (t, J=7.2 Hz, 3H, CCH₃), 1.75-1.85, 1.90-2.06 (each m, 2H, CCH₂C), 2.53 (dt, J=7 Hz, 2H, CH₂SO₃⁻), 2.88, 2.90, 2.91 (each s, 12H, N(CH₃)₂), 3.18-3.30 (m, 2H, NCH₂CH₃), 3.30-3.48 (m, 2H, NCH₂(CH₂)₂).—¹³C-NMR (125.8 MHz, CD₃CN): δ=12.14 (NCH₂CH₃), 23.14 (CCH₂CH₂), 39.16, 39.25 (NCH₃), 43.47 (NCH₂CH₃), 46.82 (CH₂SO₃⁻), 47.44 (NCH₂(CH₂)₂), 163.01 (N₃C⁺).—C₁₀H₂₃N₃O₃S (263.37): calc. C, 45.26; H, 8.74; N, 15.84; S, 12.08. found C, 45.28; H, 8.73; N, 15.77; S, 11.97.

### I.K8 4-(N,N-Diethyl-N′,N′-dipropyl-N″-octylguanidinio)butanesulfonate

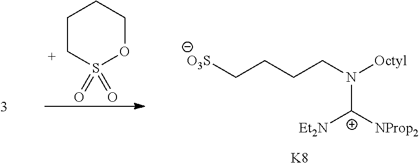

9.34 g (0.03 mol) of N,N-diethyl-N′,N′-dipropyl-N″-octylguanidine (3) give 11.48 g (85.5%) of 4-(N,N-diethyl-N′,N′-dipropyl-N″-octylguanidinio)butanesulfonate (I.K8):

light-yellow viscous mass.—¹H NMR (500 MHz, D₂O): δ=0.87-0.98 (m, 6H, CH₃), 1.20-1.34 (m, 9H, CH₃), 1.36-2.00 (m, 22H, CH₂), 2.80-3.50 (m, 12H, CH₂). ¹³C NMR (125 MHz, D₂O): δ=10.9-12.1 (CH₃), 18.0-21.7 (CH₂), 24.3-29.8 (CH₂), 41.7-42.1 (CH₂), 46.4-48.0 (CH₂), 162.1 (N₃C⁺).—C₂₃H₄₉N₃O₃S (447.72): calc. C, 61.70; H, 11.03; N, 9.39; S, 7.16. found C, 61.66; H, 10.93; N, 9.30; S, 7.12.

### I.K9 4-(N,N-Diethyl-N′,N′-ethylenedioxydiethylenedi-N″-iso-butylguanidinio)butanesulfonate

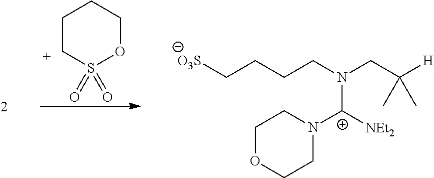

7.42 g (0.03 mol) of N,N-diethyl-N-isobutyl-N′,N′-ethylenedioxydiethylenediguanidine (2) give 4-(N,N-diethyl-N′,N′-ethylenedioxydiethylenedi-N″-isobutylguanidinio)butanesulfonate (I.K9): 10.37 g (91.5%); light-yellow solid; m.p.: 138-143° C.—¹H NMR (500 MHz, D₂O): δ=0.80-0.99 (m, 6H, CH₃), 1.15-1.28 (m, 6H, CH₃), 1.63-1.92 (m, 6H, CH₂), 1.95-2.08 (m, 1H, CH), 2.85-2.98 (m, 4H, CH₂), 3.12-3.25 (m, 4H, CH₂), 3.28-3.55 (m, 4H, CH₂), 3.75-3.98 (m, 4H, CH₂).—¹³C NMR (125 MHz, D₂O): δ=11.8-12.1 (CH₃), 19.3-19.6 (CH₃), 21.5-22.8 (CH₂), 25.6-25.9 (CH₂ and CH), 43.5-44.3 (CH₂), 47.9-50.3 (CH₂), 56.7-57.4 (CH₂), 65.4-65.9 (CH₂), 163.1 (N₃C⁺).—C₁₇H₃₅N₃O₄S (377.54): calc. C, 54.08; H, 9.34; N, 11.13; S, 8.49. found C, 53.97; H, 9.22; N, 11.04; S, 8.27.

### I.K10 N-Butyl-N′,N′,N″,N″-tetramethyl-N-[2-(N-butyl-N′,N′,N″,N″-tetramethylguanidino)ethyl]guanidinium di[bis(trifluoromethylsulfonyl)imide]

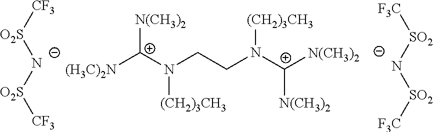

| | | |
|---|---|---|
| N-butyl-N′,N′,N″,N″-tetramethyl-N-[2-(N-butyl-N′,N′,N″,N″- | 3 mmol | 1.3 g |
| tetramethylguanidino)ethyl]guanidinium | | |
| dichloride (I.V1) (441.53 g/mol) | | |
| Bis(trifluoromethanesulfonyl)imide (281.14 g/mol) | 6 mmol | 1.7 g |

1.3 g (10 mmol) of N-butyl-N′,N′,N″,N″-tetramethyl-N-[2-(N-butyl-N′,N′,N″,N″-tetramethylguanidino)ethyl]guanidinium dichloride (V1) are dissolved in 30 ml of water and subsequently admixed with 1.7 g (6 mmol) of bis(trifluoromethanesulfonyl)imide in 20 ml of water. After stirring at room temperature for 30 minutes, the reaction mixture is evaporated on a rotary evaporator, and mixed with 50 ml of water and, after stirring for 2 hours, the precipitate is filtered off with suction and subsequently recrystallized from ethylene glycol dimethyl ether. This gives N-butyl-N′,N′,N″,N″-tetramethyl-N-[2-(N-butyl-N′,N′,N″,N″-tetramethylguanidino)ethyl]guanidinium di[bis(trifluoromethylsulfonyl)imide] (I.K10) as colorless crystals. Yield: 2.4 g (86%).

m.p. 129-130° C.—IR (ATR): ν=1600, 1549 (C═N⁺) (cm⁻¹).—¹H NMR (500.1 MHz, CD₃CN): δ=0.93 (t, 6H, J=7.3 Hz, butyl-CH₃), 1.30-1.69 (m, 8H, butyl-CH₂), 2.89, 2.92 (each s, 24H, NCH₃), 3.08-3.46 (m, 8H, NCH₂).—¹³C NMR (125.8 MHz, CD₃CN): δ=12.68 (CH₃), 19.23, 29.07, 29.28 (butyl-CH₂), 39.17, 39.53, 39.73 (NCH₃), 45.92, 47.38, 48.98 (NCH₂), 115.81, 118.36, 120.91, 123.45 (CF₃), 161.27, 163.17 (C⁺).—C₂₄H₄₆F₁₂N₈O₈S₄ (930.21): calc. C, 30.97; H, 4.98; N, 12.04; S, 13.78. found C, 31.36; H, 4.91; N, 12.11; S, 14.07.

### I.K11 N,N-Diethyl-N′,N′-dipropyl-N″-methyl-N″-[2-(N,N-diethyl-N′,N′-dipropylyl-N″-methylguanidino)ethyl]guanidinium bis(hexafluorophosphate)

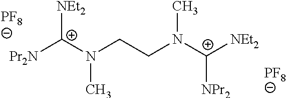

| | | |
|---|---|---|
| N,N-diethyl-N′,N′-dipropyl-N″-methyl-N″- | 4.4 mmol | 3.0 g |
| [2-(N,N-diethyl-N′,N′-dipropylyl-N″- | | |
| methylguanidino)ethyl]guanidinium bis(methylsulfate) | | |
| (I.V2) (676.42 g/mol) | | |
| Sodium hexafluorophosphate (167.95 g/mol) | 8.9 mmol | 1.5 g |

3.0 g (4.4 mmol) of N,N-diethyl-N′,N′-dipropyl-N″-methyl-N″-[2-(N,N-diethyl-N′,N′-dipropylyl-N″-methylguanidino)ethyl]guanidinium bis(methylsulfate) (I.V2) are dissolved in 50 ml of acetonitrile and subsequently admixed with 1.5 g (8.9 mmol) of sodium hexafluorophosphate. After stirring at room temperature for 40 hours, the reaction mixture is filtered, then evaporated on a rotary evaporator, admixed with 80 ml of water, stirred for 2 hours and the precipitate is filtered off with suction and subsequently recrystallized from ethylene glycol dimethyl ether. This gives N,N-diethyl-N′,N′-dipropyl-N″-methyl-N″-[2-(N,N-diethyl-N′,N′-dipropylyl-N″-methyl-guanidino)ethyl]guanidinium bis(hexafluorophosphate) (I.K11) as colorless crystals. Yield: 3.1 g (95%).

m.p. 171-172° C.—IR (ATR): ν=1539 (C═N⁺) (cm⁻¹).—¹H NMR (500.1 MHz, CD₃CN): δ=0.86-0.95 (m, 12H, NCH₂CH₂CH₃), 1.13-1.20 (m, 12H, NCH₂CH₃), 1.35-1.59, 1.64-1.82 (each m, each 4H, NCH₂CH₂CH₃), 2.88-3.61 (m, 26H, NCH₂, NCH₃).—¹³C NMR (125.8 MHz, CD₃CN): δ=10.01, 10.19, 11.40, 11.54, 11.67, 11.73, 11.79, 11.90 (CH₃), 19.99, 20.21, 20.24, 20.29, 20.33, 20.40 (CH₂), 37.55, 37.59, 37.63, 37.67, 37.73 (NCH₃), 43.27, 43.45, 43.51, 43.84, 43.92, 48.67, 48.73, 48.76, 50.59, 50.68, 50.85, 50.92, 51.15, 51.24 (NCH₂), 164.03 (C⁺).—C₂₆H₅₈F₁₂N₆P₂ (744.71): calc. C, 41.93; H, 7.85; N, 11.28. found C, 42.30; H, 7.79; N, 11.36.

### I.K12 N,N-Diethyl-N′,N′-dipropyl-N″-methyl-N″-[2-(N,N-diethyl-N′,N′-dipropylyl-N″-methylguanidino)ethyl]guanidinium (bis)trifluoromethanesulfonate

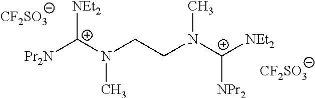

| | | |
|---|---|---|
| N,N-Diethyl-N′,N′-dipropyl-N″-methyl-N″-[2- | 4.4 mmol | 3.0 g |
| (N,N-diethyl-N′,N′-dipropylyl-N″- | | |
| methylguanidino)ethyl]guanidinium bis(methylsulfate) | | |
| (I.V2) (676.42 g/mol) | | |
| Trifluoromethanesulfonic acid (150.08 g/mol) | 9.3 mmol | 1.4 g |
| Potassium hydroxide (56.11 g/mol) | 9.3 mmol | 0.52 g |

3.0 g (4.4 mmol) of N,N-diethyl-N′,N′-dipropyl-N″-methyl-N″-[2-(N,N-diethyl-N′,N′ dipropylyl-N″-methylguanidino)ethyl]guanidinium bis(methylsulfate) (V.2) are dissolved in 30 ml of water and subsequently admixed with a solution of 1.4 g (9.3 mmol) of trifluoromethanesulfonic acid and 0.52 g (9.3 mmol) of potassium hydroxide in 20 ml of water. After stirring at room temperature for 30 minutes, the reaction mixture is evaporated on a rotary evaporator, admixed with 50 ml of water and, after stirring for 2 hours, the precipitate is filtered off with suction and subsequently recrystallized from ethylene glycol dimethyl ether. This gives N,N-diethyl-N′,N′-dipropyl-N″-methyl-N″-[2-(N,N-diethyl-N′,N′-dipropylyl-N″-methylguanidino)ethyl]guanidinium (bis)trifluoromethanesulfonate (I.K12) as colorless crystals.

Yield: 3.0 g (91%).

m.p. 141-142° C.—IR (ATR): ν=1543 (C⁺) (cm⁻¹).—¹H NMR (500.1 MHz, CD₃CN): δ=0.90-0.99 (m, 12H, NCH₂CH₂CH₃), 1.14-1.27 (m, 12H, NCH₂CH₃), 1.32-1.61, 1.62-1.89 (each m, each 4H, NCH₂CH₂CH₃), 2.88-3.67 (m, 26H, NCH₂, NCH₃).—¹³C NMR (125.8 MHz, CD₃CN): δ=9.85, 10.03, 11.24, 11.38, 11.55, 11.74 (CH₃), 19.79, 20.04, 20.13 (CH₂), 37.39, 37.50 (NCH₃), 43.06, 43.69, 48.51, 48.59, 50.37, 50.45, 51.00 (NCH₂), 113.02, 118.12, 123.22, 128.33 (CF₃), 163.83 (C⁺).—C₂₈H₅₈F₆N₆O₆S₂(752.92): calc. C, 44.67; H, 7.76; N, 11.16; S, 8.52. found C, 44.71; H, 7.82; N, 11.14; S, 8.51.

### I.K13 N,N-Diethyl-N′,N′-dipropyl-N″-methyl-N″-[2-(N,N-diethyl-N′,N′-dipropylyl-N″-methylguanidino)ethyl]guanidinium di[bis(trifluoromethylsulfonyl)imide]

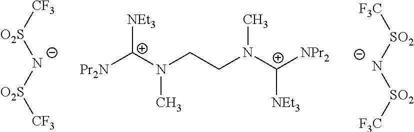

| | | |
|---|---|---|
| N,N-Diethyl-N′,N′-dipropyl-N″-methyl-N″- | 4.4 mmol | 3.0 g |
| [2-(N,N-diethyl-N′,N′-dipropylyl-N″- | | |
| methylguanidino)ethyl]guanidinium bis(methylsulfate) | | |
| (I.V2) (676.42 g/mol) | | |
| Bis(trifluoromethanesulfonyl)imide (281.14 g/mol) | 8.9 mmol | 2.5 g |
| Potassium hydroxide (56.11 g/mol) | 8.9 mmol | 0.5 g |

3.0 g (4.4 mmol) of N,N-diethyl-N′,N′-dipropyl-N″-methyl-N″-[2-(N,N-diethyl-N′,N′ dipropylyl-N″-methylguanidino)ethyl]guanidinium bis(methylsulfate) (I.V2) are dissolved in 30 ml of water and subsequently admixed with a solution of 2.5 g (8.9 mmol) of bis(trifluoromethanesulfonyl)imide and 0.5 g (8.9 mmol) of potassium hydroxide in 20 ml of water. After stirring at room temperature for 30 minutes, the reaction mixture is evaporated on a rotary evaporator, admixed with 50 ml of water and, after stirring for 2 hours, the precipitate is filtered off with suction and subsequently recrystallized from ethylene glycol dimethyl ether. This gives N,N-diethyl-N′,N′-dipropyl-N″-methyl-N″-[2-(N,N-diethyl-N′,N′-dipropylyl-N″-methylguanidino)ethyl]guanidinium di[bis(trifluoromethylsulfonyl)imide] (I.K13) as colorless crystals. Yield: 3.6 g (81%).

m.p. 122-123° C.—IR (ATR): ν=1542 (C═N⁺) (cm⁻¹).—¹H NMR (500.1 MHz, CD₃CN): δ=0.86-0.95 (m, 12H, NCH₂CH₂CH₃), 1.13-1.24 (m, 12H, NCH₂CH₃), 1.38-1.59, 1.63-1.83 (each m, each 4H, NCH₂CH₂CH₃), 2.84-3.59 (m, 26H, NCH₂, NCH₃).—¹³C NMR (125.8 MHz, CD₃CN): δ=9.98, 10.16, 10.18, 11.40, 11.53, 11.65, 11.71, 11.78, 11.88, 11.93 (CH₃), 20.01, 20.18, 20.21, 20.29, 20.36 (CH₂), 37.60, 37.65, 37.68, 37.73 (NCH₃), 43.26, 43.46, 43.52, 43.84, 43.91, 48.68, 48.72, 48.76, 50.59, 50.70, 50.86, 50.86, 50.93, 51.61, 51.24 (NCH₂), 115.82, 118.37, 120.92, 123.47 (CF₃), 164.00 (C⁺).—C₃₀H₅₈F₁₂N₈O₈S₄ (1015.07): calc. C, 35.50; H, 5.76; N, 11.04; S, 12.64. found C, 35.85; H, 5.76; N, 11.04; S, 12.73.

### II. Electrochemical Characterization of the Guanidinium Compounds

For the electrochemical characterization, cyclic voltammetry studies were carried out on the proposed class of compounds. These data were obtained for ionic liquids containing

II.1 Guanidinium cations and
II.2 Guanidinium betaines.

BMIMPF6 (1-butyl-3-methylimidazolium hexafluorophosphate) was used as standard reference material. A platinum wire having an area of 0.1 cm² served as working electrode. Platinum wires likewise served as reference electrode and counterelectrode. Ferrocene was used as internal standard.

Furthermore, the influence of the solvent (11.3) on the electrochemical behavior of the compounds was generally examined for some illustrative compounds.

### II.1 Guanidinium Monocations

FIG. 2 shows a cyclic voltammogram of the compounds M7a/b (N,N-dihexyl-N′,N′-dimethyl-N″,N″-pentamethyleneguanidinium tetrafluoroborate) and M8 (N,N-dihexyl-N′,N′-dimethyl-N″,N″-pentamethyleneguanidinium hexafluorophosphate) compared to the reference BMIMPF6. When the electrochemical stability window of M7a and M8 is looked at, it becomes clear that both M8 and M7a/M7b are more stable than the standard reference. While in the present cyclic voltammetry setup BMIMPF6 covers an electrochemical window of about 4.5 V, a window of >7 V is found for the two guanidinium representatives. Here, M8 seems to be even slightly more stable than M7a/M7b. An insulating effect is observed neither for M8 nor for M7a/M7b.

### II.2 Guanidinium Betaines

Betaines are ionic compounds in which anion and cation are joined to one another by a covalent bond, so that they are not separated, but can be aligned, by electric fields. The molecules are electrically neutral but have barely delocalized, spatially separated charges. Tests were carried out on the betaines K2, K3, K6, K7, K8 and K9, which have a covalently bound sulfonate anion on an alkyl radical of a hexaalkylguanidinium cation. Here, the betaines K6 and K8 are ionic liquids at room temperature, and the remainder, on the other hand, are present as solids at room temperature.

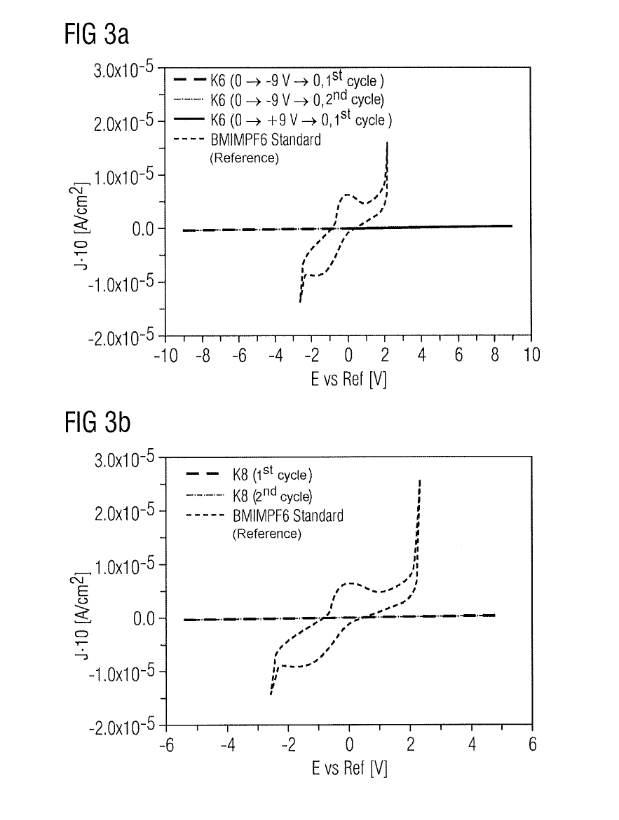

The results of the cyclic voltammetry measurements on the compound K6 are shown in FIG. 3a and the results of the cyclic voltammetry measurements on the compound K8 are shown in FIG. 3b.

It is conspicuous that, in comparison with the reference, no oxidative or reductive current flow was measured in the entire voltage range from −9 V to +9 V. The materials display virtually no conductivity and thus, as insulator, a wide electrochemical window (here >18 V). This shows their particular suitability for forming thin-film capacitors.

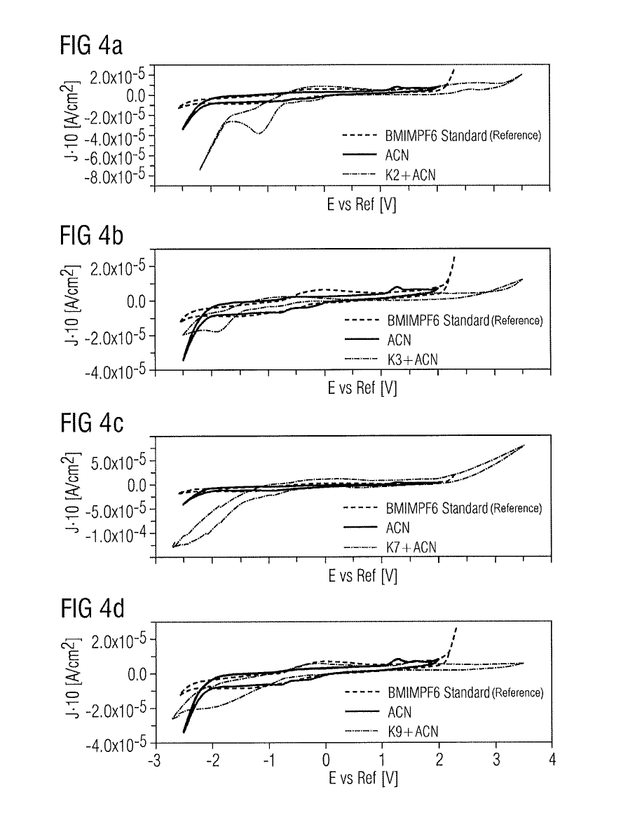

The FIGS. 4a-4d show the cyclic voltammetry measurements for the solid betaines K2, K3, K7 and K9. In addition, the corresponding spectrum for pure acetonitrile and the BMIMPF6 standard reference are also depicted.

It is conspicuous that the electrochemical stability of the solid compounds K2, K3, K7 and K9 is lower than that of the two betaine liquids K6 and K8. The stability window here fluctuates in the range from 3.5 V to 5.5 V. In contrast thereto, the stability window for K6 and K8 is significantly larger (>10 V). Although the cyclic voltammetry curves of the solid betaines are shifted to more positive voltages compared to pure acetonitrile, an influence of the solvent cannot be ruled out here. The electrochemical decomposition of the solvent above the redox parameters also has a fragmenting effect on the guanidinium salts, reductively more strongly than oxidatively. Without solvent, the stability of the solid compounds can certainly be comparable to those of the liquid betaines (see also section II.3).

### II.3 Solvent Influence

Solvents additionally introduced into the system can influence the electrochemical stability of ionic liquids. This effect has been demonstrated for the example of the material K6 (4-(N,N-dimethyl-N′,N′,N″-tripropylguanidinio)butanesulfonate) and various solvents.

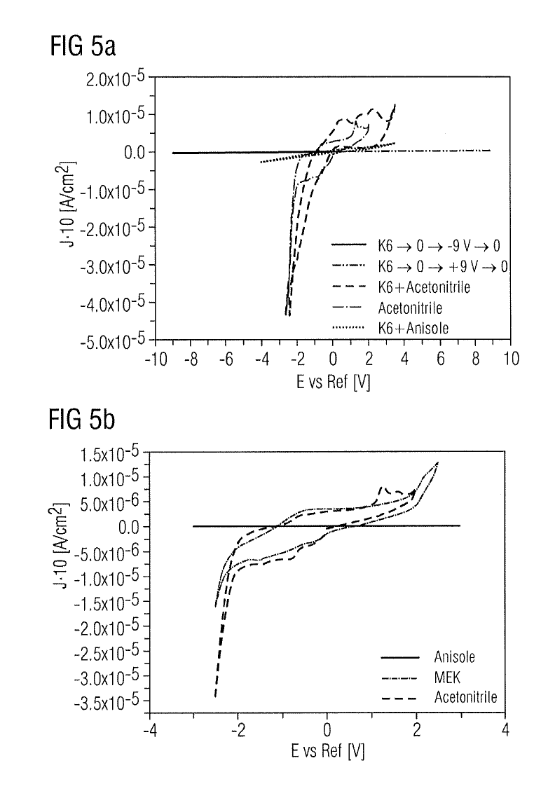

FIG. 5a shows the cyclic voltammetry data of the compound K6 in various solvents. FIG. 5b, on the other hand, shows the cyclic voltammetry behavior of only the solvent. It can be seen that the measured solvents anisole, MEK and acetonitrile decrease the electrochemical stability window of the material. The observed reduction of the electrochemical stability is smallest in the case of anisole. Significant differences between acetonitrile and MEK could not be observed.

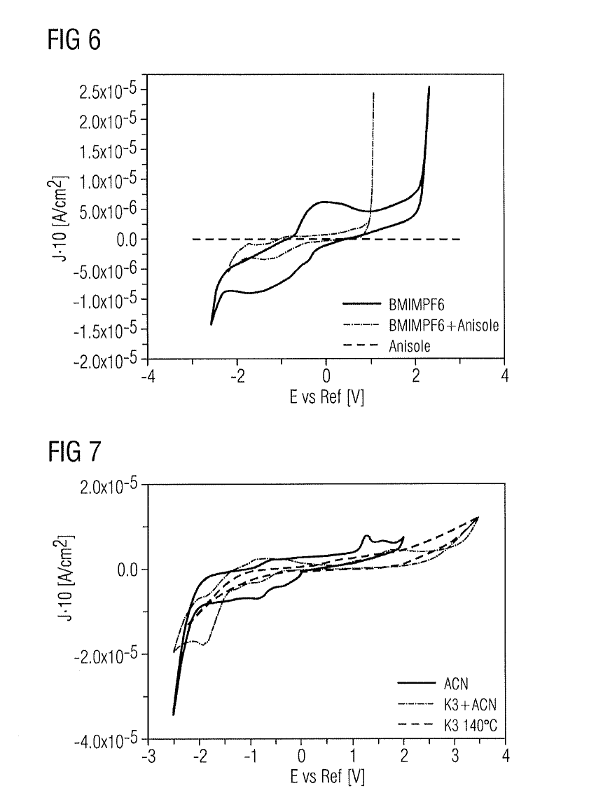

Measurements on the reference material BMIMPF6 (FIG. 6) show that, in comparison with pure BMIMPF6, a combination of BMIMPF6 and anisole has a significantly smaller electrochemical window. Anisole is presumably electrochemically oxidized in the presence of this IL to form bis-4,4′-dimethoxybiphenyl. Support for this could be given by the fact that it is known that, for example, Lawesson's reagent, i.e. an oxidatively produced insertion compound of anisole and phosphorus(V) sulfide, can extremely easily be formed (see also authors collective, Organicum, 20th edition (1996) 481-482).

In addition, it can be seen from FIG. 6 that pure anisole behaves as an insulator and does not initiate any redox processes.

For a further cyclic voltammetric analysis of a solvent influence, the behavior of K3 (3-(N,N-dimethyl-N′,N′,N″-tripropylguanidinio)propanesulfonate) in a melt was compared with the behavior of a K3 and acetonitrile solution (see FIG. 7). In the melt at 140° C., a current flow is in fact measured, in contrast to the compounds K6 and K8. The material does not act as an insulator. This is an indication that the influence of the solvent cannot be completely ruled out but no dominant behavior is present.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-15. (canceled)

16. A two-layer, dielectric layer for a thin-film capacitor, comprising:
a lower layer comprising a self-assembled monolayer containing a phosphoroxo compound; and
an upper second layer serving as a planarization layer, the planarization layer containing a guanidinium compound.

17. The two-layer, dielectric layer as claimed in claim 16, wherein the guanidinium is at least one compound selected from the group consisting of guanidinium salts, bisguanidinium salts and guanidinium betaines.

18. The two-layer, dielectric layer as claimed in claim 16, wherein the planarization layer comprises a guanidinium salt whose cation corresponds to the formula (IV) below: 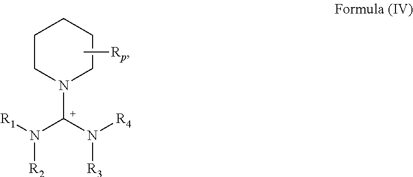
where Rₚ is a branched, unbranched or cyclic C1-C20 alkyl, heteroalkyl, aromatic, or heteroaromatic, and
each of R₁-R₄ is selected independently from the group consisting of branched or unbranched C1-C20 alkyls, heteroalkyls, oligoethers, oligoesters, oligoamides, oligoacrylamides.

19. The two-layer, dielectric layer as claimed in claim 16, wherein the guanidinium compound of the planarization layer contains anions selected from the group consisting of fluorophosphates, fluoroborates, phenylborates, sulfonylimides, trifluoromethanesulfonates, bis(trifluoromethylsulfonyl)imides, sulfonates, sulfates, chlorides, bromides and benzoates.

20. The two-layer, dielectric layer as claimed in claim 16, wherein the planarization layer has a thickness less than or equal to 10 000 nm.

21. The two-layer, dielectric layer as claimed in claim 16, wherein the phosphoroxo compound of the self-assembled monolayer is at least one compound selected from the group consisting of organic phosphonic acids, organic phosphonic esters and phosphonic acid amides.

22. The two-layer, dielectric layer as claimed in claim 16, wherein the phosphoroxo compound of the self-assembled monolayer correspond to the general formula (VI)
CH₃—(CH₂)ₙ—PO(OH)₂ Formula (VI),
where n is greater than or equal to 2 and less than or equal to 25.

23. The two-layer, dielectric layer as claimed in claim 16, wherein the planarization layer additionally comprises a polymeric substance.

24. The two-layer, dielectric layer as claimed in claim 23, wherein the polymeric substance is at least one substance selected from the group consisting of epoxides, polyacrylates, polyurethanes, polycarbonates, polyesters, polyamides, polyimides, polybenzoxazoles, polyvinylidene difluorides, polyvinyl compounds, polycarbazoles and phenol/formaldehyde compounds.

25. The two-layer, dielectric layer as claimed in claim 17, wherein the planarization layer comprises a guanidinium salt whose cation corresponds to the formula (IV) below: 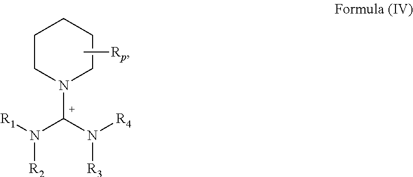
where Rₚ is a branched, unbranched or cyclic C1-C20 alkyl, heteroalkyl, aromatic, or heteroaromatic, and
each of R₁-R₄ is selected independently from the group consisting of branched or unbranched C1-C20 alkyls, heteroalkyls, oligoethers, oligoesters, oligoamides, oligoacrylamides.

26. The two-layer, dielectric layer as claimed in claim 25, wherein the guanidinium compound of the planarization layer contains anions selected from the group consisting of fluorophosphates, fluoroborates, phenylborates, sulfonylimides, trifluoromethanesulfonates, bis(trifluoromethylsulfonyl)imides, sulfonates, sulfates, chlorides, bromides and benzoates.

27. The two-layer, dielectric layer as claimed in claim 26, wherein the planarization layer has a thickness less than or equal to 10 000 nm.

28. The two-layer, dielectric layer as claimed in claim 27, wherein the phosphoroxo compound of the self-assembled monolayer is at least one compound selected from the group consisting of organic phosphonic acids, organic phosphonic esters and phosphonic acid amides.

29. The two-layer, dielectric layer as claimed in claim 28, wherein the phosphoroxo compound of the self-assembled monolayer correspond to the general formula (VI)
CH₃—(CH₂)ₙ—PO(OH)₂ Formula (VI),
where n is greater than or equal to 2 and less than or equal to 25.

30. A process for producing a thin-film capacitor having a two-layer, dielectric layer, comprising:
providing a substrate support having a first electrode;
applying a self-assembled monolayer containing an organic phosphorus oxo compound to the substrate support and the first electrode;
applying a planarization layer containing a guanidinium compound to the self-assembled monolayer; and
applying a metallic layer as a second electrode, to the planarization layer.

31. The process for producing a thin-film capacitor as claimed in claim 30, wherein at least one of the self-assembled monolayer and the planarization layer is applied by spin coating, slot coating, printing, centrifugation, dipping, curtain coating or doctor blade coating.

32. The process for producing a thin-film capacitor having a two-layer, dielectric layer as claimed in claim 30, wherein
the planarization layer additionally comprises crosslinkable compounds, and
the process further comprises crosslinking the crosslinkable compounds with one another.

33. An electrical component comprising:
a first electrode layer;
a two-layer, dielectric layer comprising a self-assembled monolayer containing a phosphoroxo compound formed on the first electrode layer and a planarization layer containing a guanidinium compound formed on the self-assembled monolayer; and
a second electrode layer arranged on top of the two-layer, dielectric layer.

34. The electronic component as claimed in claim 33, wherein the electronic component is a storage capacitor in an electronic circuit.

35. The electronic component as claimed in claim 33, wherein the electronic component is arranged on a circuit board substrate, a prepreg or a circuit board.
